(19) United States
(12) Patent Application Publication
(10) Pub. No.: US 2026/0187323 A1
(43) Pub. Date: Jul. 2, 2026

(54) SMART PHYSICS-INSPIRED COMPOSITIONAL DIMENSIONLESS TYPE CURVES FOR ENHANCED OIL RECOVERY

(71) Applicant: University of Kansas, Lawrence, KS (US)

(72) Inventors: Amirmasoud Kalantari Dahaghi, Lawrence, KS (US); Fahad Iqbal Syed, Lawrence, KS (US)

(21) Appl. No.: 19/129,722

(22) PCT Filed: Nov. 16, 2023
(86) PCT No.: PCT/US2023/080171

§ 371 Date: May 14, 2025

Related U.S. Application Data
(60) Provisional application No. 63/426,650, filed on Nov. 18, 2022.

(51) Int. Cl. G06F 30/28; G06F 30/27

(52) U.S. Cl. CPC G06F 30/28; G06F 30/27

(57) ABSTRACT

Systems and methods of the present disclosure provide functionality for generating type curves for enhanced oil recovery (EOR) in a physics compliant manner. To generate type curves for EOR, a data set associated with one or more properties of a reservoir is obtained and used to predict a dynamic response indicating properties of a predicted recovery of hydrocarbons from the reservoir. The dynamic response may be evaluated to determine whether the dynamic response covers one or more target properties. Additional data for the data set may be generated using simulations if the dynamic response does not cover the one or more target properties. The data set is used to train an artificial intelligence (AI) algorithm configured to generate one or more type curves for EOR. Once trained, the AI algorithm may generate at least one type curve indicating one or more properties of hydrocarbon recovery during EOR.

### CROSS REFERENCE TO RELATED APPLICATIONS

The present application claims the benefit of priority from U.S. Provisional Patent Application No. 63/426,650 , filed Nov. 18, 2022 and entitled “SMART PHYSICS-INSPIRED COMPOSITIONAL DIMENSIONLESS TYPE CURVES FOR ENHANCED OIL RECOVERY” the disclosure of which is incorporated by reference herein in its entirety.

### TECHNICAL FIELD

The present application generally relates to production of hydrocarbon and more specifically, to systems and methods for optimizing production of hydrocarbons during enhanced oil recovery (EOR) of hydrocarbon production processes.

### BACKGROUND

The production of hydrocarbons, such as oil and gas, is a complex task involving many different types of equipment, processes, and other factors. For example, prior to drilling a well there may be many different types of testing performed (e.g., seismological testing, surveys, geological studies, etc.) to determine whether the tested area(s) are a viable location for drilling a well. Once a well site is identified and the well is drilled, the well may begin a primary production stage, which is a phase of hydrocarbon recovery in which hydrocarbons are extracted from the reservoir without any modification of the reservoir (i.e., no fluid injection, fracturing of the rock at the well site, etc.). Many different factors can impact the duration of the primary production stage and the amount and/or rate at which hydrocarbons are produced during primary production. For example, reservoir properties (e.g., porosity of the formation, size, pressure, and other properties), hydrocarbon properties (e.g., very light oil, light oil, medium oil, heavy oil, oil mixed with other gases, etc.), and other factors. Due to these different factors, wells may produce hydrocarbons at different rates during primary production and the length of time before production begins to degrade may also vary.

Steps may be taken to improve hydrocarbon recovery when primary production begins to decline. Such processes, referred to as enhanced oil recovery (EOR), involve alteration of the reservoir properties to improve the recovery of hydrocarbons. For example, a fluid (e.g., water, carbon dioxide (CO2), etc.) may be injected into the reservoir to fracture the rock formation of the reservoir and release the hydrocarbons trapped in pores of the rock formation, thereby releasing oil trapped in the rock formation of the reservoir. The release of the oil from the pores of the rock formation increases the amount of hydrocarbons in the reservoir that may be recovered by one or more wells of the reservoir and enhancing the amount of hydrocarbons recovered from the well relative to the amount of hydrocarbons that would have been captured otherwise (e.g., by remaining in primary production).

A type curve is a tool that may be used to predict the production performance of hydrocarbon reservoirs. While systems for generating type curves are known, existing systems for generating type curves are not suitable for use in EOR phases of hydrocarbon production. One factor that renders existing systems inadequate is the need to account for physical laws that impact the behavior of the reservoir during EOR. For example, injection of the fluid into the reservoir may change the composition of the hydrocarbons in the reservoir or the rock properties of the reservoir (e.g., due to fracturing of the rock formation). Such changes are impacted by the laws of physics and existing systems cannot account for the physics-based impact on the reservoir behavior, much less do so with certainty. Accordingly, using existing type curves for EOR operations may result in an inaccurate understanding of the reservoir behavior, which may lead to selection of locations for performing EOR operations that are less than optimal, creating waste and inefficiencies with respect to hydrocarbon recovery.

### SUMMARY

Aspects of the present disclosure provide systems, methods, and computer-readable storage media supporting operations and functionality for generating type curves for enhanced oil recovery (EOR) operations. To support the disclosed functionality, a data set may be obtained. The data set may include field data obtained from sensors and other equipment used to monitor production of hydrocarbons from the reservoir or other sources (e.g., data obtained prior to beginning production and drilling a well, such as reservoir geological properties or other types of data). The dataset may be used to predict a dynamic response indicating properties of a predicted recovery of hydrocarbons from the reservoir.

As explained above, field data may be limited or insufficient to adequately characterize and analyze a reservoir. For example, generating the dynamic response solely based on field data may result in an incomplete characterization of the dynamic reservoir response, resulting in gaps or missing information in the dynamic response. In an aspect, this problem may be addressed using numerical simulation. To illustrate, an initial dynamic response generated based on the data set may be evaluated to determine whether the dynamic response covers one or more target properties. If the dynamic response does not adequately cover the one or more target properties, one or more simulations may be performed to generate additional data for the data set. The process of evaluating the dynamic response and performing simulations may be repeated until the dynamic response derived or generated from the data set adequately covers the one or more target properties.

The data set, once complete, may be used to train an artificial intelligence (AI) algorithm that is configured to generate one or more type curves for EOR. As explained above, existing systems provide functionality for generating type curves during a primary production phase of hydrocarbon recovery. However, such systems are inadequate for use in generating type curves for EOR phases of hydrocarbon recovery since EOR introduces factors that are not present during primary production and therefore, do not need to be accounted for when generating type curves for primary production phases of hydrocarbon recovery. For example, in primary production a well is drilled and then production begins. In such a scenario, the production of hydrocarbons does not significantly alter properties of the reservoir (e.g., rock properties, hydrocarbon composition properties, etc.) and as such, these prior systems for generating type curves do not need to account for physics defined behaviors of the reservoir or changes to those behaviors. In contrast, EOR operations involve injecting a fluid into the reservoir, which may alter or impact the behavior of the reservoir. For example, injecting a fluid (e.g., CO₂, water, etc.) into the reservoir may alter a composition of the hydrocarbons in the reservoir, impact properties related to fluid and rock interactions (e.g., fracturing rock of the reservoir to release hydrocarbon from pores within the rock, etc.), or other changes to properties of the reservoir that are subject to the laws of physics.

Due to the changes to the reservoir properties or behaviors during EOR, a type curve generation system designed to generate type curves for EOR phases of hydrocarbon recovery should account for the impact of physical laws on the reservoir properties, which will improve the accuracy of and the information conveyed by the type curves. Accordingly, in an aspect, the training process may be configured to validate and verify that the AI algorithm learns or is learning physics defined behaviors of the reservoir. For example, parameters of the AI algorithm representing those properties of the reservoir (e.g., rock properties, fluid properties, etc.) impacted by physics may be associated with physics defined behaviors. Associating the parameters of the AI algorithm with physics defined behaviors may provide a mechanism for enabling the model to learn those physics defined behaviors and how they impact the properties of the reservoir. For example, a physics defined behavior may indicate that as a property of the reservoir changes, the behavior of the reservoir is expected to change in a particular way (e.g., shift, increase, etc.). During training, scores indicating whether the AI algorithm is learning or has learned the relevant physics defined behaviors may be generated, thereby providing a mechanism for validating that the AI algorithm is accounting for the impact that physical laws have on the reservoir response.

Once training is complete, the AI algorithm may be able to generate type curves that are suitable for EOR phases of hydrocarbon recovery (e.g., because the AI algorithm can account for the impact that physical laws and EOR operations have on the reservoir) and accurately model the behaviors of the reservoir during EOR. The type curves generated in accordance with the present disclosure may be used to identify candidate wells within a reservoir that represent potential locations (e.g., well locations) for utilizing EOR. For example, the type curves may indicate information indicating a predicted enhancement to recovery of hydrocarbons (e.g., relative to primary production) during EOR. Furthermore, the type curves may be associated with different sets of properties, such as fluid properties (e.g., hydrocarbon composition properties, a type of fluid to inject, a volume of fluid to inject, etc.) and rock properties (e.g., rock properties associated with the reservoir at the injection site). Thus, a type curve may be used to identify candidate wells within the reservoir by identifying which wells of the reservoir are associated with the relevant properties of the type curve. Once the candidate wells are identified, an operator may finalize a strategy for performing EOR in the reservoir (e.g., selection of specific wells where EOR is to be performed and starting EOR).

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific aspects disclosed may be readily utilized as a basis for modifying or designing other structures for carrying out the same purposes of the present disclosure. It should also be realized by those skilled in the art that such equivalent constructions do not depart from the scope of the disclosure as set forth in the appended claims. The novel features which are disclosed herein, both as to organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following descriptions taken in conjunction with the accompanying drawings, in which:

FIG. 1 is a block diagram of a system for generating type curves in accordance with aspects of the present disclosure;

FIG. 2 is a block diagram illustrating an exemplary process for generating type curves in accordance with aspects of the present disclosure;

FIG. 3A shows a diagram of an exemplary type curve generated in accordance with aspects of the present disclosure;

FIG. 3B shows a diagram of an exemplary type curve generated in accordance with aspects of the present disclosure;

FIG. 4A shows a diagram of a process for using Design of Experiments (DoE) to generate type curves in accordance with aspects of the present disclosure;

FIG. 4B shows another diagram of a process for using DoE to generate type curves in accordance with aspects of the present disclosure;

FIG. 4C shows a diagram illustrating a process for performing gap analysis in accordance with aspects of the present disclosure;

FIG. 5A shows a diagram with type curves for reservoirs exhibiting placement shift for reservoirs exhibiting downward shift for heavier to lighter reservoir fluid type in accordance with aspects of the present disclosure;

FIG. 5B shows a diagram with type curves for RTA of reservoirs exhibiting placement shift for reservoirs exhibiting downward shift for heavier to lighter reservoir fluid type in accordance with aspects of the present disclosure;

FIG. 5C shows a diagram with type curves for reservoirs exhibiting placement shift for increasing reservoir porosity in accordance with aspects of the present disclosure;

FIG. 5D shows a diagram with type curves for RTA of reservoirs exhibiting placement shift for increasing reservoir porosity in accordance with aspects of the present disclosure;

FIG. 5E shows a diagram with type curves for reservoirs exhibiting placement shift for increasing hydraulic fracture half-length in accordance with aspects of the present disclosure;

FIG. 5F shows a diagram with type curves for RTA of reservoirs exhibiting placement shift for reservoirs exhibiting crossover shifts for increasing fracture half-length in accordance with aspects of the present disclosure;

FIG. 5G shows a diagram with type curves for reservoirs exhibiting placement shift for increasing hydraulic fracture height in accordance with aspects of the present disclosure;

FIG. 5H shows a diagram with type curves for RTA of reservoirs exhibiting placement shift for reservoirs exhibiting increasing hydraulic fracture height in accordance with aspects of the present disclosure;

FIG. 5I shows a diagram with type curves for reservoirs exhibiting placement shift for increasing hydraulic fracture conductivity in accordance with aspects of the present disclosure;

FIG. 5J shows a diagram with type curves for RTA of reservoirs exhibiting placement shift for reservoirs exhibiting increasing hydraulic fracture conductivity in accordance with aspects of the present disclosure;

FIG. 6A shows a diagram with type curves for reservoirs exhibiting placement shift for lighter to heavier reservoir fluid types in accordance with aspects of the present disclosure;

FIG. 6B shows a diagram with type curves for RTA of reservoirs exhibiting placement shift for reservoirs exhibiting crossover shifts for lighter to heavier reservoir fluid types in accordance with aspects of the present disclosure;

FIG. 6C shows a diagram with type curves for reservoirs exhibiting placement shift for increasing reservoir porosity in accordance with aspects of the present disclosure;

FIG. 6D shows a diagram with type curves for RTA of reservoirs exhibiting placement shift for reservoirs exhibiting increasing reservoir porosity in accordance with aspects of the present disclosure;

FIG. 6E shows a diagram with type curves for reservoirs exhibiting placement shift for increasing hydraulic fracture half-length in accordance with aspects of the present disclosure;

FIG. 6F shows a diagram with type curves for RTA of reservoirs exhibiting placement shift for reservoirs exhibiting increasing hydraulic fracture half-length in accordance with aspects of the present disclosure;

FIG. 6G shows a diagram with type curves for reservoirs exhibiting placement shift for increasing hydraulic fracture height in accordance with aspects of the present disclosure;

FIG. 6H shows a diagram with type curves for RTA of reservoirs exhibiting placement shift for reservoirs exhibiting increasing hydraulic fracture height in accordance with aspects of the present disclosure;

FIG. 6I shows a diagram with type curves for reservoirs exhibiting placement shift for increasing hydraulic fracture conductivity in accordance with aspects of the present disclosure;

FIG. 6J shows a diagram with type curves for RTA of reservoirs exhibiting placement shift for reservoirs exhibiting increasing hydraulic fracture conductivity in accordance with aspects of the present disclosure;

FIG. 7 is a block diagram illustrating aspects of optimization of hydrocarbon production using type curves in accordance with aspects of the present disclosure; and

FIG. 8 is a flow diagram of an exemplary method for generating enhanced oil recovery (EOR) type curves in accordance with aspects of the present disclosure.

It should be understood that the drawings are not necessarily to scale and that the disclosed aspects are sometimes illustrated diagrammatically and in partial views. In certain instances, details which are not necessary for an understanding of the disclosed methods and apparatuses or which render other details difficult to perceive may have been omitted. It should be understood, of course, that this disclosure is not limited to the particular aspects illustrated herein.

### DETAILED DESCRIPTION

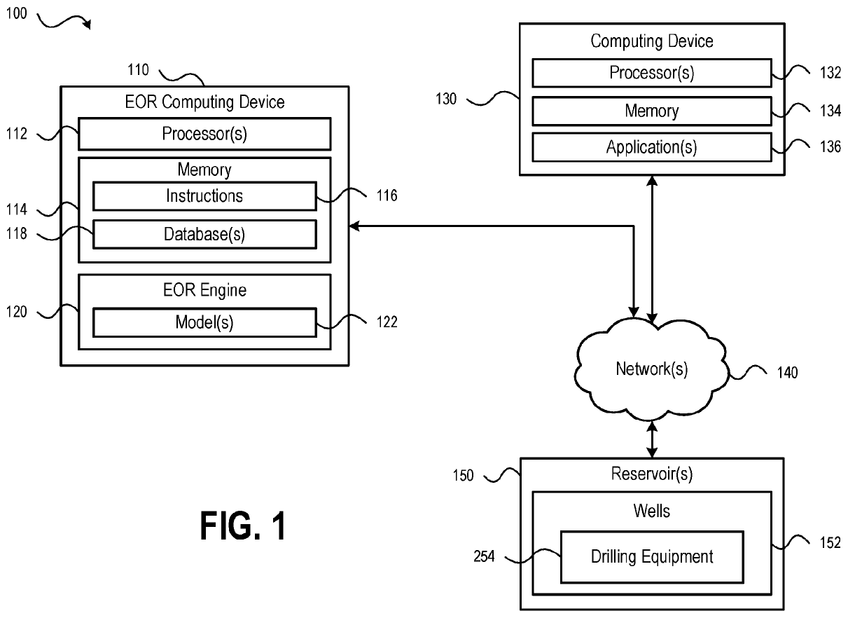

Referring to FIG. 1, a block diagram of a system for generating type curves in accordance with aspects of the present disclosure is shown as a system 100. As shown in FIG. 1, the system 100 includes an enhanced oil recovery (EOR) computing device 110. As explained in more detail below, the EOR computing device 110 provides functionality supporting generation of type curves for EOR processes associated with wells within a reservoir. In an aspect, the type curves may provide information associated with one or more optimization parameters, such as parameters associated with what are referred to herein as W3H factors, which include: where to inject one or more fluids into the reservoir during EOR, when to inject the fluid(s) into the reservoir for EOR, what fluid(s) to inject into the reservoir for EOR, how to inject the fluid(s) into the reservoir for EOR, or a combination thereof. It is noted that in the examples described herein various type curves generated by the EOR computing device 110 are described with respect to optimization of EOR operations during a secondary production stage of production of hydrocarbons from a reservoir. However, it should be understood that the concepts disclosed herein for generating type curves may readily be applied to generation of type curves for optimization of tertiary or later stages of EOR production of hydrocarbons from a reservoir.

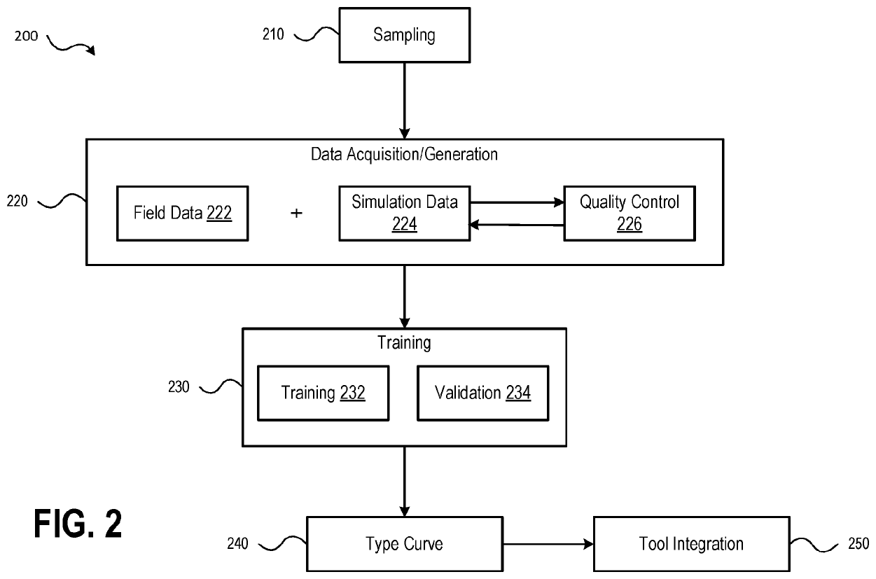

As shown in FIG. 1, the EOR computing device 110 includes one or more processors 112, a memory 114, and an EOR engine 120. The one or more processors 112 may include one or more microcontrollers, application specific integrated circuits (ASICs), field programmable gate arrays (FPGAs), central processing units (CPUs) and/or graphics processing units (GPUs) having one or more processing cores, or other circuitry and logic configured to facilitate the operations of the PCI modelling device 110 in accordance with aspects of the present disclosure. The memory 114 may include random access memory (RAM) devices, read only memory (ROM) devices, erasable programmable ROM (EPROM), electrically erasable programmable ROM (EEPROM), one or more hard disk drives (HDDs), one or more solid state drives (SSDs), flash memory devices, network accessible storage (NAS) devices, or other memory devices configured to store data in a persistent or non-persistent state. Operations of the EOR computing device 110 may be embodied as software stored as instructions 116 in the memory 114 that, when executed by the one or more processors 112, cause the one or more processors 112 to perform the operations for generating type curves for optimizing EOR, as described herein with respect to the EOR computing device 110 and FIGS. 2-8. Information used to support the operations and functionality of the EOR computing device 110 with respect to generating type curves for EOR in accordance with aspects of the present disclosure may be stored in the memory 114 as one or more databases 118. Exemplary types of data that may be stored in the database(s) 118 to support operations of the EOR computing device 110 are described in more detail below.

The EOR engine 120 provides functionality for generating type curves for optimizing EOR in accordance with aspects of the present disclosure. For example, the functionality provided by the EOR engine 120 may optimize one or more parameters for EOR operations, such as where to inject one or more fluids into the reservoir for EOR, when to inject the fluid(s) into the reservoir for EOR, what fluid(s) to inject into the reservoir for EOR, how to inject the fluid(s) into the reservoir for EOR, or a combination thereof. The EOR engine 120 may utilize artificial intelligence models or algorithms to generate the types curves. In an aspect, the artificial intelligence models or algorithms may be trained using physics compliance indicator (PCI) techniques to support generation of physics-based dimensionless performance type curves, as described in more detail below. Exemplary PCI techniques that may be used to validate compliance of the AI with applicable physics laws are described in co-pending and commonly owned U.S. Provisional Application No. 63/426,641(UKAN.P0033US.P1 ) entitled “Physics Compliance Indicator (PCI) for Machine Learning,” filed on Nov. 18, 2022, the contents of which are incorporated herein by reference in its entirety. As described in more detail below, type curves generated by the EOR engine 120 in accordance with the present disclosure may be configured to optimize various parameters for EOR and/or UEOR, such as injection solvent type and volume, the optimum start of injection and soaking time as well as the frequency of this cyclic process and estimation of the soaking duration. Optimization of such parameters using type curves in accordance with the present disclosure may provide for optimum oil recovery across a variety of different well types, reservoirs, or other factors.

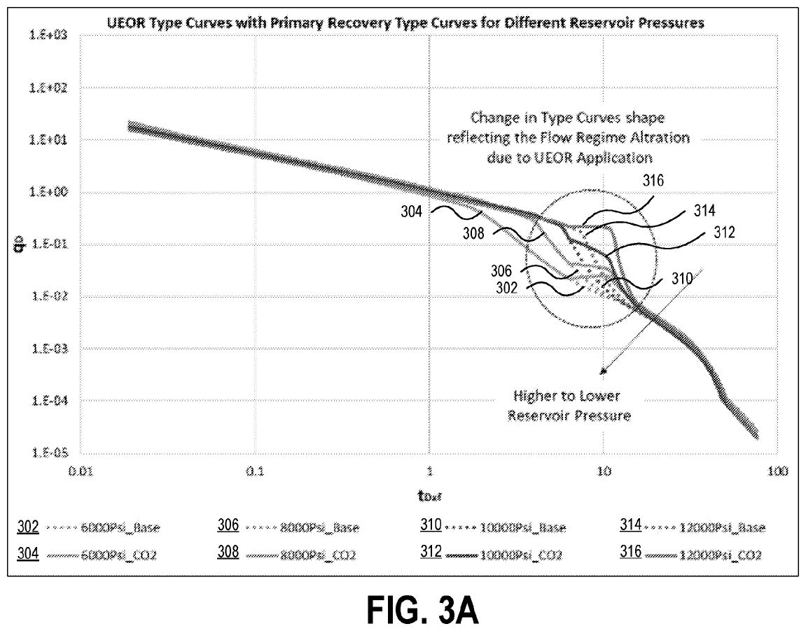

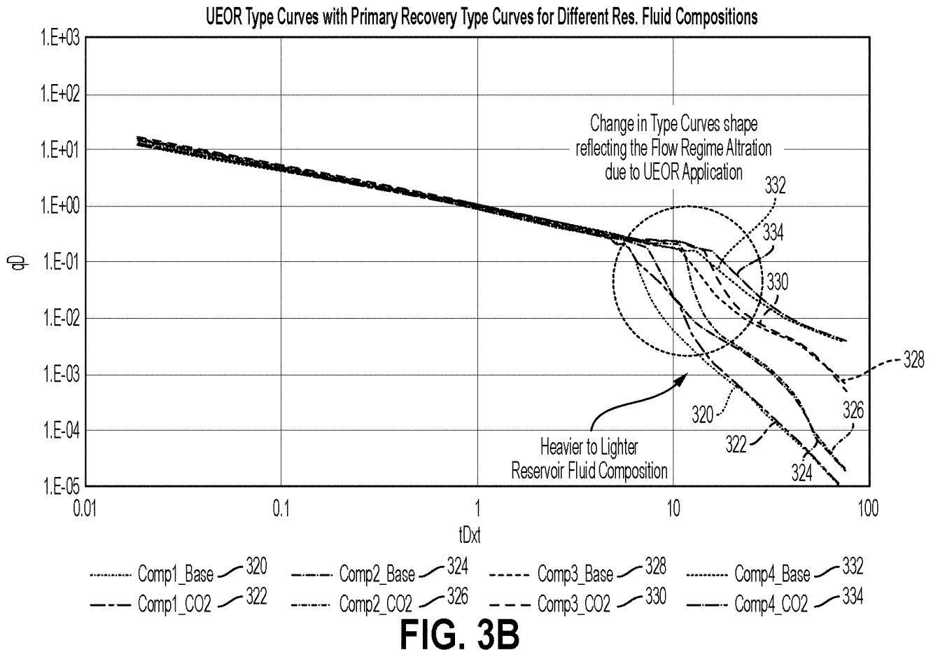

As an illustrative example and referring briefly to FIGS. 3A and 3B, exemplary type curves generated in accordance with aspects of the present disclosure are shown. The exemplary type curves shown in FIGS. 3A and 3B represent unconventional EOR (UEOR) smart physics-inspired compositional dimensionless type curves (SPIC TCs) generated in accordance with aspects of the present disclosure. For example, the type curves of FIGS. 3A and 3B may be generated by an EOR computing device, such as the EOR computing device 110 of FIG. 1 having the EOR engine 120, and may enable operators to quickly identify candidate wells for UEOR and EOR operations, as well as optimization of EOR operations at one or more of the identified candidate wells.

In FIGS. 3A and 3B the dashed lines (e.g., lines 302, 306, 310, 314 in FIG. 3A and lines 320, 324, 328, 332 in FIG. 3B) show the base performance of an unconventional producing well (e.g., during primary production) and the solid lines (e.g., lines 304, 308, 312, 316 in FIG. 3A and lines 322, 326, 330, 334 in FIG. 3B) show expected performance of the same well when it goes through the UEOR process with CO₂ and/or hydrocarbon gas as EOR injected fluid (injectant solvent). As shown in the legend of FIG. 3A, the expected performance or response of the well(s) represented by the different lines 302-316 vary according reservoir pressure, while the legend of FIG. 3B illustrates the expected performance or response of the well(s) represented by the different lines 320-332 vary according fluid compositions (e.g., heavier to lighter fluid compositions). As can be seen in the type curves of FIGS. 3A and 3B, the expected performance of the well is predicted to increase (solid lines) relative to the base case (dashed lines) due to UEOR/EOR activities.

Referring back to FIG. 1, generation of type curves using the EOR engine 120 may provide insights into expected performance of a well based on a variety of factors (e.g., reservoir pressure (FIG. 3A) and fluid composition (FIG. 3B). As described in more detail below, the dimensionless type curves generated by the EOR engine 120 may be SPIC TCs (e.g., physics-based dimensionless performance type curves) suitable for use in applications involving EOR and UEOR, rather than merely primary productions as in currently available type curves and type curve generation systems. As described in more detail below, the EOR engine 120 may be configured to utilize a Physics Informed Design of Experiment (PI-DoE) methodology to generate type curves for EOR. The PI-DoE methodology may utilize a combination of techniques to improve the way in which type curves are generated. For example, the functionality provided by the EOR engine 120 may utilize simulation techniques to generate data sets covering a target range of response properties. The target range of response properties may correspond to a range of properties that adequately characterizes possible properties of a reservoir and/or well. Exemplary reservoir/well properties may include fluid properties (e.g., whether the oil is heavy, light, very light, etc., pressure, volume, etc.), rock properties (e.g., type of rock present in the reservoir, porosity, and permeability of the rock, etc.), rock and fluid interaction properties, hydraulic fracture properties (e.g., fracture conductivity, fracture half-length and fracture height, the number of hydraulic fracture clusters per stage, etc.), and operational constraints (e.g., equipment constraints; resource constraints, such as access to a fluid to perform injection; soaking time after injecting the EOR fluid; etc.). By covering a range of properties for the reservoir/wells, the EOR engine 120 may account for variations of the properties of a reservoir (e.g., reservoirs may include different rock properties, fluid properties, rock and fluid interaction properties, hydraulic fracture design properties, and operational constraints), which enable type curves to be generated that account for different sets of properties covering a particular portion of a reservoir (e.g., a portion of the reservoir associated with particular wells) or an entire reservoir.

The EOR engine 120 may provide functionality for performing validation and quality control operations to improve the quality of the resulting type curves. For example, the quality control operations may include a gap analysis process that may be used to evaluate and control the simulation process to ensure the generated data sets cover the target range of parameters. In an aspect, the quality control operations may be performed iteratively with the simulation. To illustrate, the simulation process may be performed and then the quality control operations may be performed to evaluate whether sufficient data has been generated (e.g., data covering the target range of properties). Once it is determined (e.g., via the quality control operations) that the target range of properties are covered by the generated data sets, the EOR engine 120 may use the data sets to generate and train an artificial intelligence model 122, such as a neural network. The artificial intelligence model 122 may be trained using the data sets generated by the EOR engine 120 and may be used to generate type curves for EOR in accordance with aspects of the present disclosure once training is complete. The EOR engine 120 may support a validation process that may be utilized during the training of the artificial intelligence model 122. The validation process may be used to ensure the artificial intelligence model 122 complies with and learns the physics associated with the reservoir(s)/well(s) under consideration, which may be represented by the data sets generated by the EOR engine.

The above-described functionality provided by the EOR engine 120 will now be described in more detail with reference to FIG. 2, which shows a block diagram illustrating an exemplary process 200 for generating type curves in accordance with aspects of the present disclosure. In an aspect, the exemplary process 200 for generating type curves for EOR shown in FIG. 2 may be performed by a computing device, such as the EOR computing device 110 of FIG. 1 and more specifically, the EOR engine 120 of FIG. 1. The process 200 may begin at block 210, where sampling is performed. During sampling, information associated with reservoir and well properties may be identified. For example, information associated with fluid properties, rock properties, rock and fluid interaction properties, hydraulic fracture design properties, engineering and operational constraints, and other properties may be identified. The properties identified during the sampling may be utilized to ensure sufficient data for characterizing the reservoir and/or wells acquired or generated to facilitate generation of type curves in accordance with aspects of the present disclosure, as described in more detail below.

One challenge with present techniques for generation of type curves for primary production of hydrocarbons is the lack of data and/or accuracy of available data and the inability to account for physics of the reservoir and wells, which leads to inaccurate modelling of the reservoir and use of the model to predict the response of the reservoir over time and changes. This problem is compounded when considering type curves for EOR in which the physics of the reservoir change due to the injection of fluids into the reservoir. As an example of the challenge presented by lack of data, hundreds or thousands of wells may be drilled in a reservoir, but any single entity trying to generate type curves for the reservoir may only have information associated with a fraction of the existing wells. This lack of data for the complete reservoir results in data sets that do not adequately predict or characterize the response of the reservoir across all properties or combinations of properties, which can lead to inaccuracies when using these incomplete data sets to generate type curves. As briefly explained above and in more detail below, the EOR engine 120 of FIG. 1 may provide functionality to overcome the above-identified challenges.

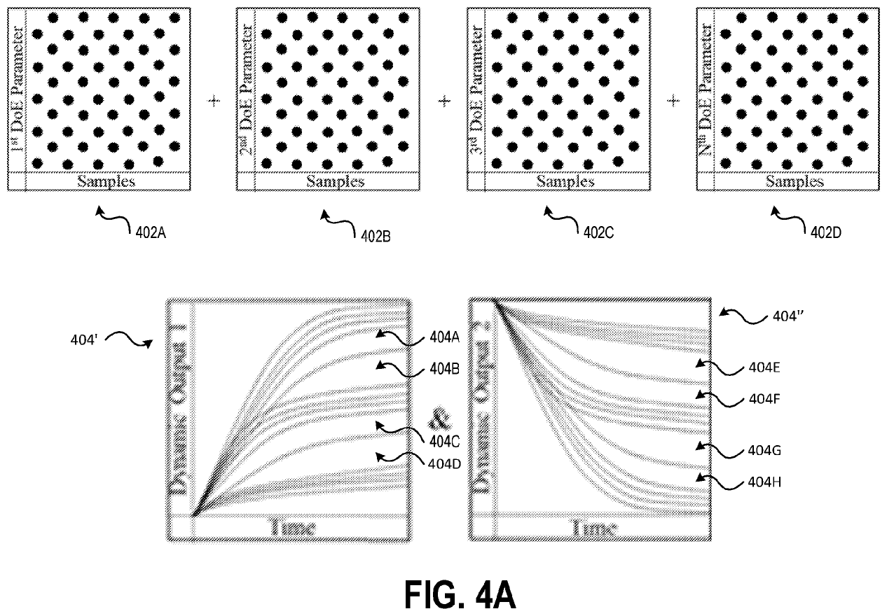

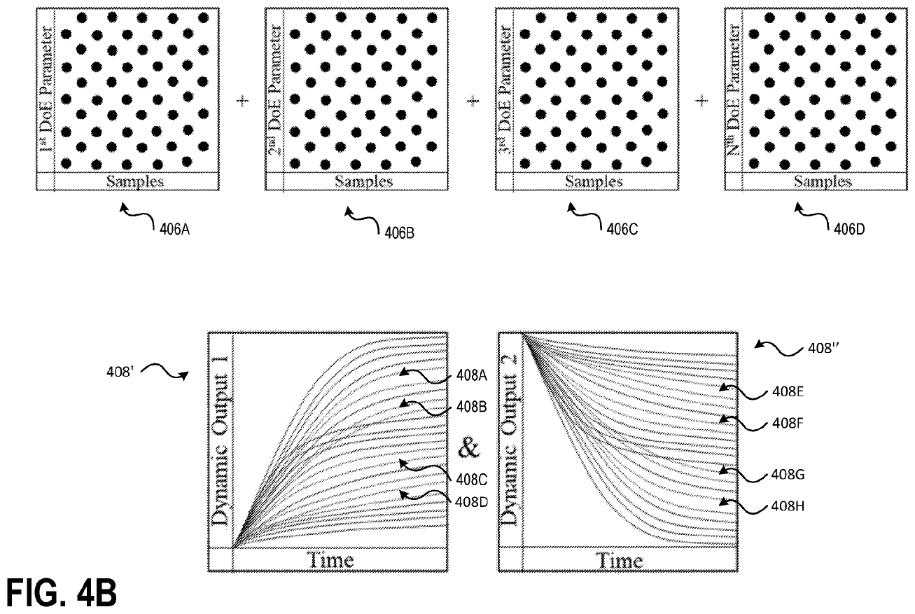

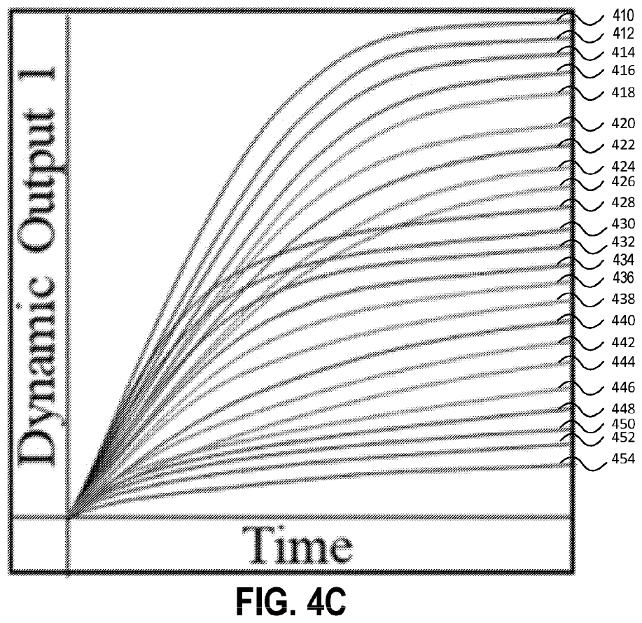

As an illustrative example of the challenges that can arise when using incomplete data sets to generate type curves and referring to FIG. 4A, a schematic of a conventional DoE for generating type curves is shown. In FIG. 4A, random distributions of samples 402A-402D across a given sampling range for a physics-defined system (e.g., a reservoir) are shown. For example, each of the random distributions of samples 402A-402D may be associated with different types of well properties, reservoir properties, fluid compositions, or other properties. In an aspect, the samples 402A-402D may be generated using a Latin Hypercube Sampling (LHS) technique (e.g., during sampling at block 210 of FIG. 2), which may enable different combinations of the available properties to be created, such as sets of properties covering an entire range of possible property values and combinations of properties. For example, using Latin hypercube sampling may enable sets of properties to be constructed that contain unique sets of properties or combinations of properties (e.g., a first set of properties may have rock property 1, fluid property A, fluid composition property X; a second set of properties may have rock property 3, fluid property B, fluid composition property Y; and a third set of properties may have rock property 1, fluid property B, fluid composition property X). It is noted that LHS sampling technique described above is advantageous as it provides a proxy modeling approach that evenly distributes samples over a given sampling space, where each sample (e.g., samples 402A-402D and 406A-406D) may be referred to as a controlled random sample, which may be applied in Monte Carlo uncertainty quantification analysis because it can dramatically reduce the number of simulations that are needed to achieve accurate results. Similarly, for a huge database development using a deterministic simulation approach, LHS helps to reduce the sampling points significantly. However, it should be understood that other sampling techniques may be utilized in accordance with aspects of the present disclosure. The samples 402A-402D provide a set of properties for a reservoir/well that may be used to produce a set of dynamic response outputs, shown in FIG. 4A as dynamic response outputs 404A and 404′, 404″. The output 404′ represents cumulative production of a well or reservoir while the output 404″ represents the instantaneous production rates over time. Due to inaccuracies in the data sets the outputs 404′, 404″ may be incomplete. For example, it can be seen in FIG. 4A that the outputs 404′, 404″ have gaps 404A-404H, indicating the outputs 404′, 404″ represent an incomplete representation of the response(s) of the reservoir(s)/well(s) determined based on the samples 402A-402D. Such incomplete responses may be realized when relying on field data alone (e.g., the field data 222 of FIG. 2). As will be described in more detail below, the presence of the gaps 404A-404H indicates an incomplete understanding of the reservoir and well(s) based on the available data sets.

Referring back to FIG. 2, to address the incomplete data sets problem outlined above with reference to FIG. 4A, the EOR engine 120 may utilize a data acquisition process, at block 220, to obtain field data 222 associated with one or more reservoirs (e.g., data obtained from measurements at one or more wells associated with a reservoir, data characterizing properties of the reservoir, or other types of information obtained from the reservoir or a well site). In an aspect, one or more simulations may be used to generate additional data, shown in FIG. 2 as numerical simulation data 224, covering an entire range of possible parameters and values for a given reservoir, thereby supplementing the field data 222 and providing a more comprehensive data set associated with the reservoir. The additional information provided by the numerical simulation data 224 enables more accurate generation (e.g., by the EOR computing device 110 of FIG. 1 and more specifically, the EOR engine 120 of FIG. 1) of type curves for EOR, as described in more detail below. In an aspect, the numerical simulation may be performed (e.g., by the EOR engine 120 of FIG. 1) iteratively until a stop condition is achieved to ensure adequate parameter coverage. For example and referring to FIG. 4B, it can be seen that incorporating the additional data (e.g., the numerical simulation data 224 of FIG. 2) provided by numerical simulation in the samples 406A-406D, the gaps 404A-404D in cumulative production output 404′ of FIG. A are filled by plots 408A-408D in cumulative production output 408′ and that the gaps 404E-404H in cumulative production output 404″ of FIG. A are filled by plots 408E-408H in cumulative production output 408′ . In an aspect, the samples 406A-406D may be generated using a Latin hypercube sampling technique. As will be described in more detail below, a quality control process implemented in accordance with aspects of the present disclosure may be used to perform a gap analysis configured to determine when sufficient data has been generated via simulation to cover the range of target parameters.

Referring back to FIG. 2, it can be seen (e.g., from FIGS. 4A and 4B) that using numerical simulation enables a more complete understanding of the potential response range of a reservoir(s) and/or well(s). As briefly described above, the numerical simulation may be performed over many cycles or iterations (e.g., thousands of iterations) and may produce an interactive or on-demand library of reservoir/well responses based on different properties. As shown at block 226, a quality control process may be used to determine when a stop condition associated with the numerical simulation is achieved (i.e., when to stop numerical simulation). For example, a series of numerical simulations may be performed and dynamic response outputs (e.g., the outputs 404′, 404″ of FIG. 4A and the outputs 408′, 408″ of FIG. 4B) may be generated. A gap analysis process may be used to evaluate whether any gaps are present in the responses, which may indicate the data sets are incomplete. In an aspect, the gap analysis may involve a user reviewing the dynamic response outputs to determine whether gaps are present or not. If the user determines gaps are present, the user may initiate additional simulations to generate additional data and new response outputs may be generated for gap analysis. In an additional or alternative aspect, the gap analysis may be performed automatically. As an illustrative and non-limiting example, pairs of dynamic responses may be evaluated to determine a metric (e.g., distance) and the metric may be evaluated to determine if the metric is within a threshold tolerance (e.g., a threshold distance, within x percent of a target distance, etc.). A gap may be detected when a metric associated with one or more pairs of dynamic responses does not satisfy the threshold tolerance, and additional numerical simulations may be performed upon detection of one or more gaps. The additional data generated by the additional numerical simulations may be used to generate additional dynamic responses and the gap analysis may be performed again until no gaps are detected or a threshold number of simulations have been performed. It is noted that the above-described gap analysis process, whether performed by a user or automatically, may take several iterations or cycles and the properties may be varied during each iteration or cycle to improve the likelihood that the entire response range is adequately covered.

As an illustrative example of the gap analysis described above and referring to FIG. 4C, a diagram illustrating a process for performing gap analysis in accordance with Aspects of the present disclosure is shown. FIG. 4C shows a dynamic response output including responses 410-454, where the responses 410-454 may represent a final dynamic response output (e.g., after a gap analysis stop condition is satisfied). Suppose the dynamic response of FIG. 4C included responses 410-416, 422, 424, 428-434, 440, and 448-454 after initially being generated, which would look similar to the response 404′ of FIG. 4A. During gap analysis it may be determined that four gaps are present (e.g., gaps 404A-404D of FIG. 4A). As explained above, the gaps may be identified by a user or may be identified by determining metrics associated with pairs of responses (e.g., responses 410/412, responses 412/414, and so on) and determining whether the metrics satisfy a threshold tolerance. For example, after the initial dynamic response is generated, gaps may be detected based on the metrics associated with the response pairs 416/422, 422/428, 424/440, and 440/448 not satisfying the threshold tolerance.

Upon determining that gaps are present, additional numerical simulations may be performed to generate additional data that may be used to generate a new dynamic response. Suppose that after the second cycle of numerical simulation the responses 418, 420 are present. In such an instance, gaps associated with the response pairs 422/428, 424/440, and 440/448 may remain, but the gap associated with the response pair 416/422 may no longer be present (e.g., due to the presence of responses 418, 420). During subsequent iterations of the numerical simulation additional responses may be produced, such as responses 424, 426, 436, 438, 442, 444, 446, and this process may continue until the dynamic response is determined to adequately cover the response range.

Referring back to FIG. 2, once the data generation/acquisition process is complete and data covering the complete range of reservoir and well properties has been generated (e.g., as indicated by achieving the stop condition for the quality control process of block 226), the process 200 may generate, train, and validate one or more artificial intelligence models (e.g., the model(s) 122 of FIG. 1), as shown at block 230. In an aspect, the one or more artificial intelligence models may include one or more neural networks, such as one or more deep neural networks, gradient boosting algorithms, or other techniques. It is noted that other types of artificial intelligence models or algorithms may be utilized and that neural networks have been disclosed for purposes of illustration, rather than by way of limitation. During training, at block 232, the data sets generated by the data generation/acquisition process described with reference to block 220 may be used to train the artificial intelligence model(s) for type curve generation. For example, the data sets may be used to build a proxy model for EOR and UEOR type curve generation, rather than being limited to primary production as in existing techniques. In an aspect, the artificial intelligence model or algorithm may be configured to receive, as input, information associated with one or more properties of a reservoir and well, such as the properties described above, and to solve the fluid flow of the reservoir and well for the given set of parameters, thereby predicting the response or recovery of hydrocarbons from a well based on the parameters input to the model(s).

As briefly described above, artificial intelligence models or algorithms used in accordance with the present disclosure to generate the types curves may be configured to account for the impact of physics when determining the response of the reservoir (e.g., how injection of a fluid into a reservoir exhibiting certain properties impacts hydrocarbon recovery). As solving the fluid flow of the reservoir in response to injection of a fluid represents a problem that is impacted by physics (e.g., how the injected fluid impacts fracture of the rock of the formation, how the fractures impact release of oil that may be captured or recovered, etc.), the training of the model(s) or algorithm(s) may utilize PCI techniques to support generate of physics-based dimensionless performance type curves. The PCI techniques may be configured to associate PCI hyperparameters with the model(s) or algorithm(s), where each PCI hyperparameter represents parameter impacted by physics applicable to the modeled system (e.g., a reservoir or well) and is associated with physics defined behaviors (PDBs) representing or indicating expected responses/behavior changes with respect to variation of input parameter values due to the impact of physics. As an example, injecting a fluid into the reservoir may change fluid properties of the hydrocarbons in the reservoir (e.g., change a composition of the hydrocarbons and/or change a pressure of the reservoir based on a volume and type of fluid injected into the reservoir). Using PCI techniques enables hyperparameters to be configured to evaluate whether the model(s) or algorithm(s) learn the physics associated with these changes, such as to learn that as the volume of fluid injected in the reservoir increases the composition of the hydrocarbons changes (e.g., a gradient change) or that the pressure in the reservoir increases (e.g., a shift). Using PCI techniques enables the model(s) to be validated, at block 234, as complying with the physics, thereby improving the resulting type curves generated by the model(s). Detailed aspects of PCI techniques that may be used to validate compliance of the AI with applicable physics are described in co-pending and commonly owned U.S. Provisional Application No. 63/426,641(UKAN.P0033US.P1 ) entitled “Physics Compliance Indicator (PCI) for Machine Learning,” filed on Nov. 18, 2022, the contents of which are incorporated herein by reference in its entirety.

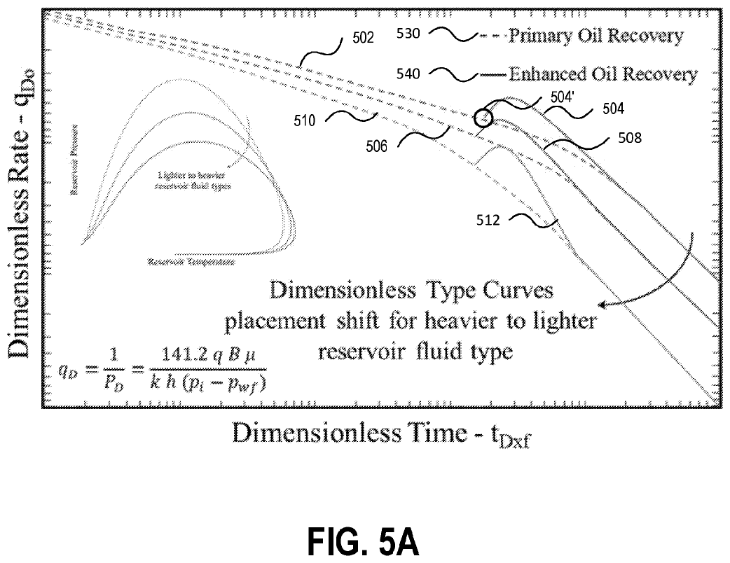

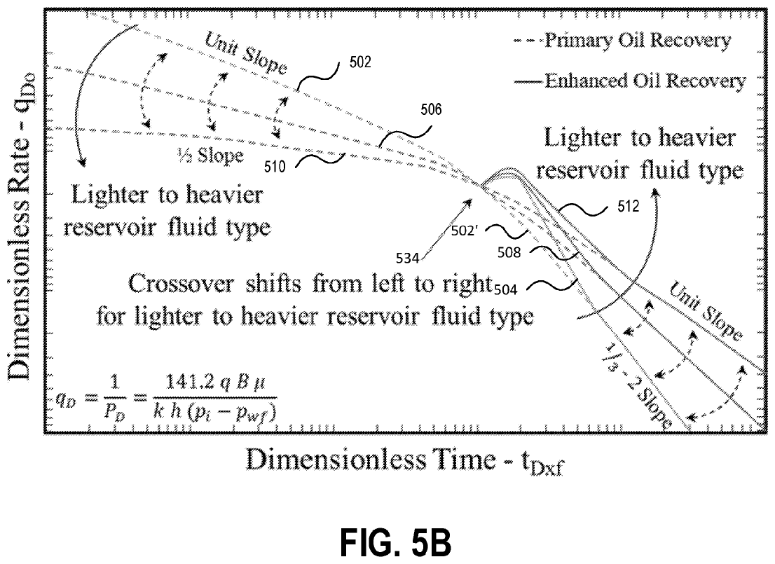

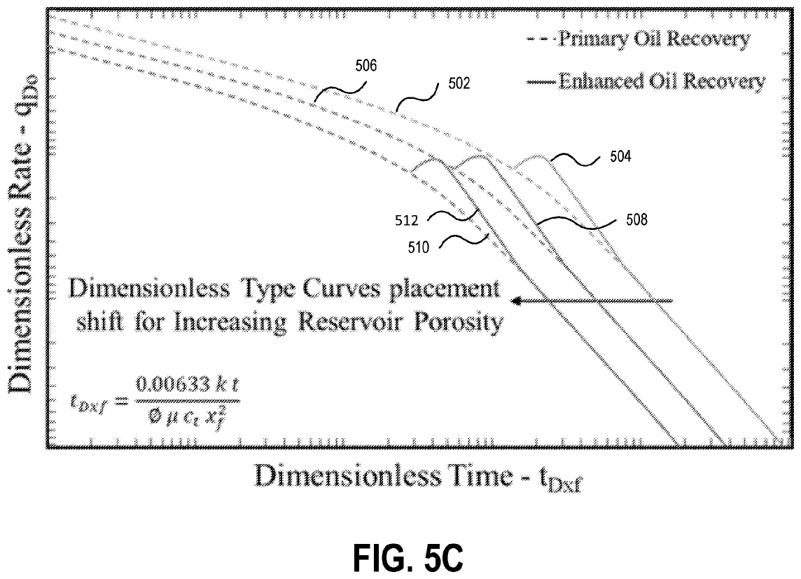

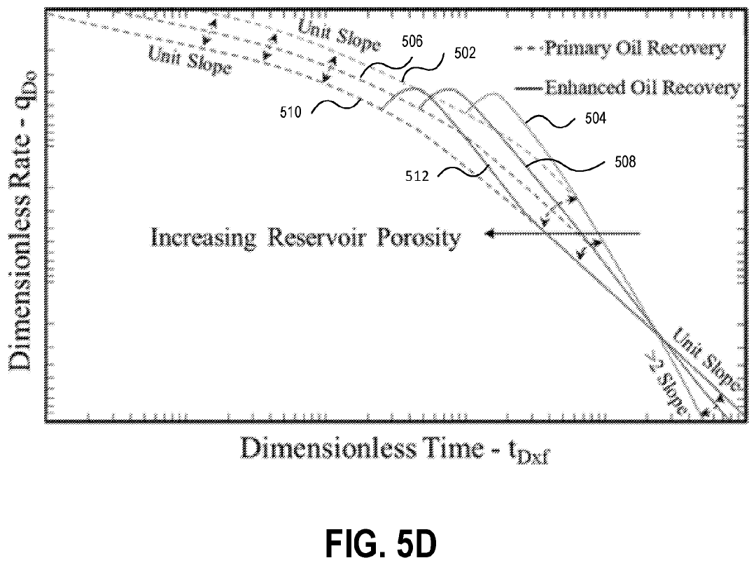

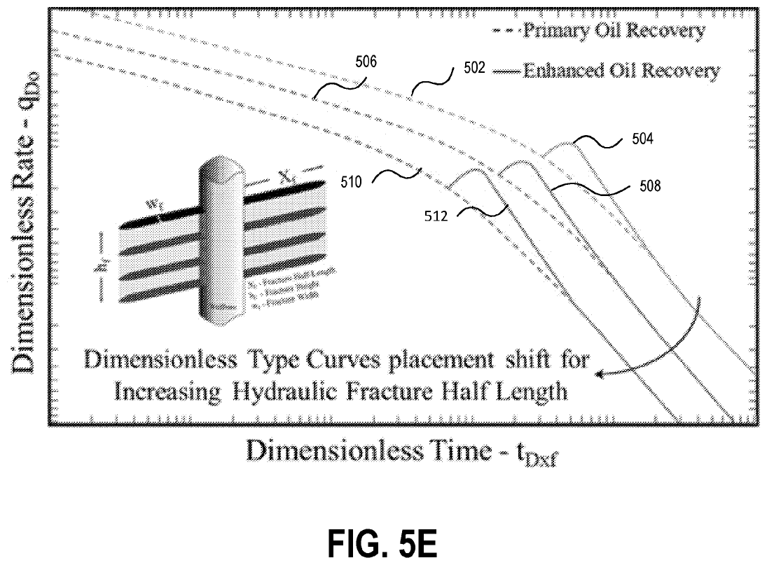

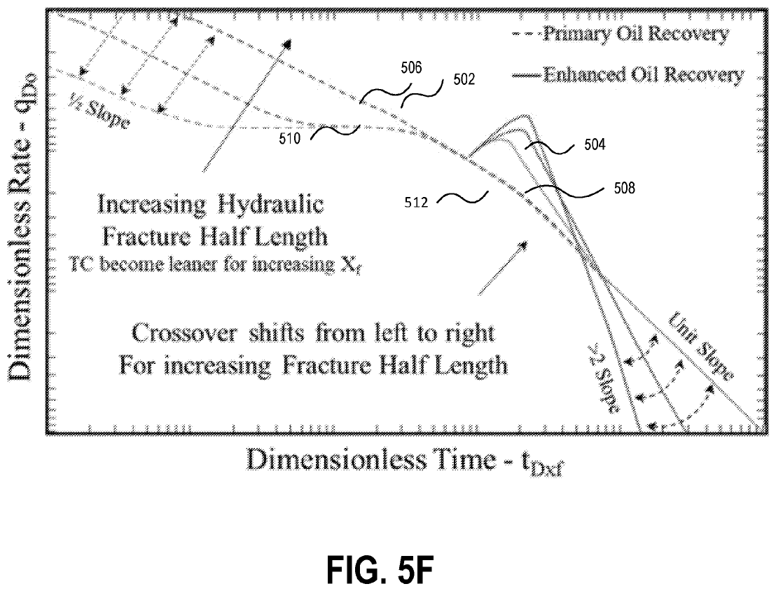

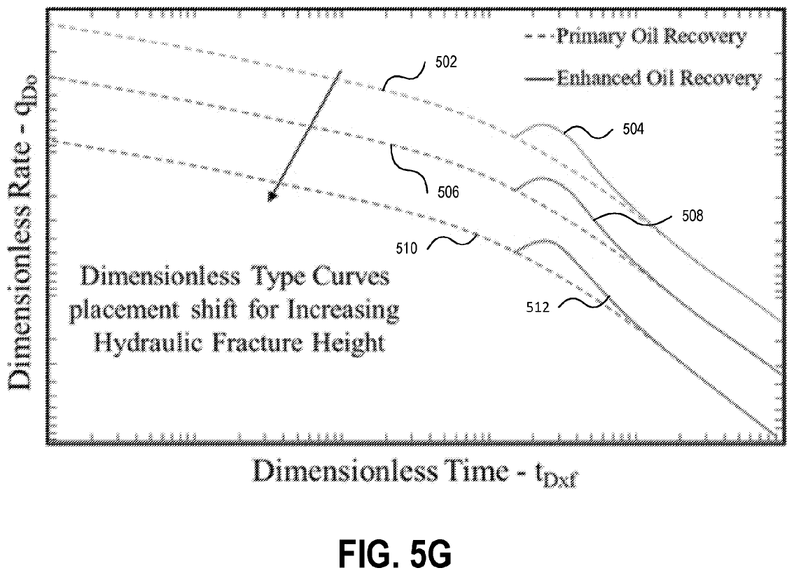

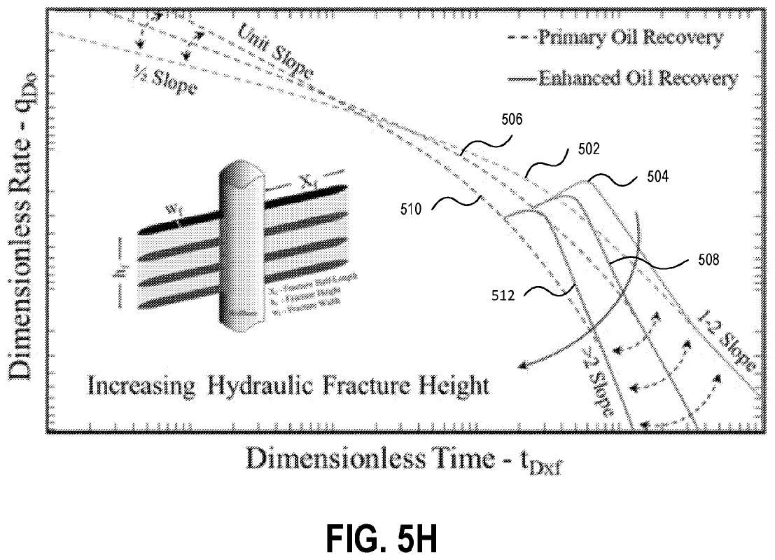

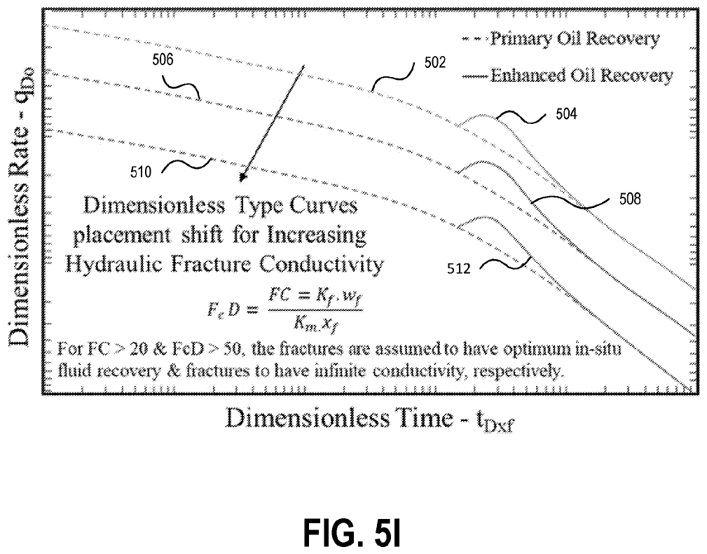

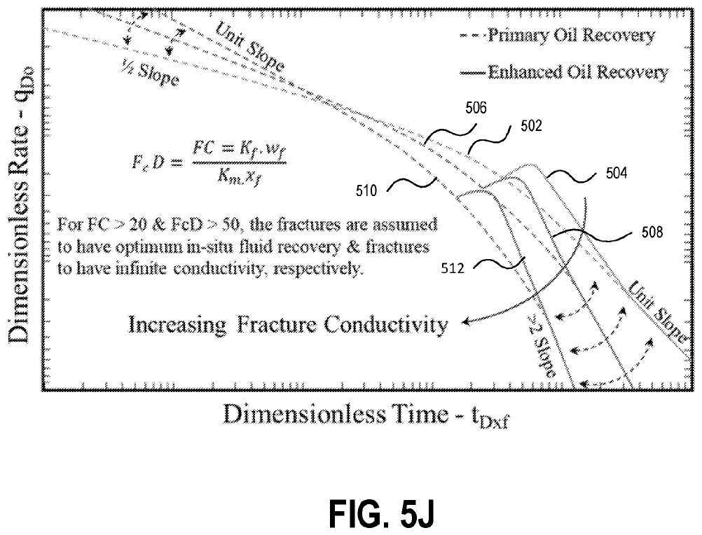

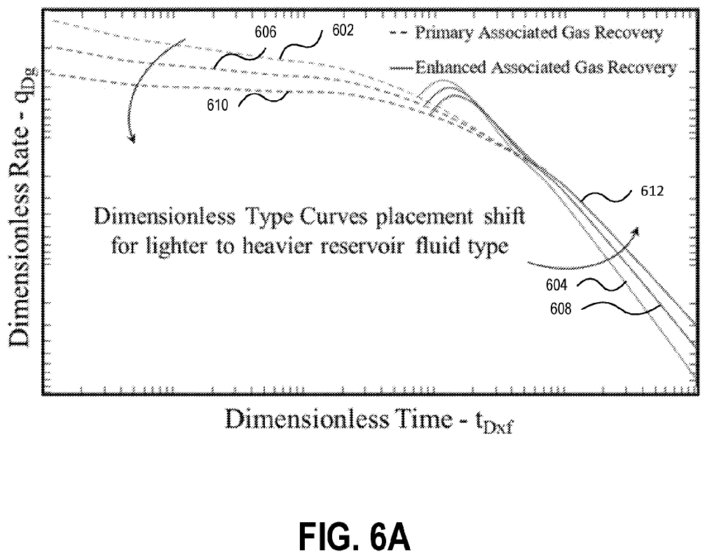

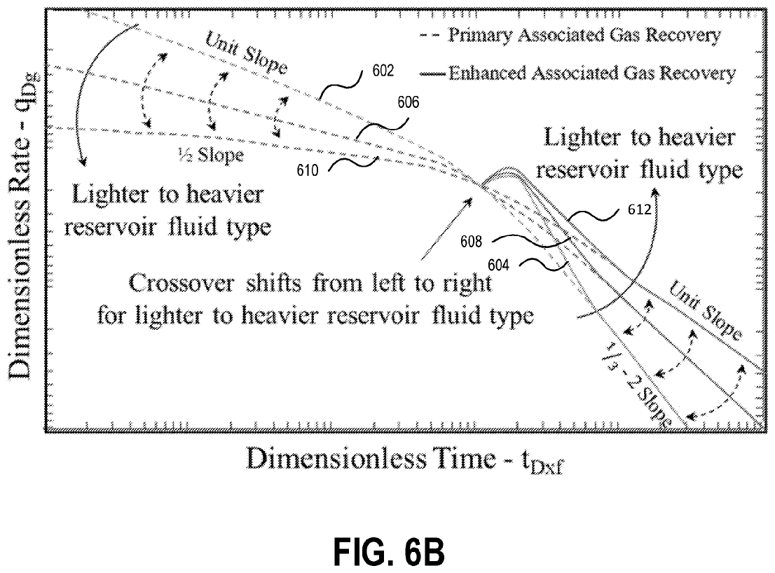

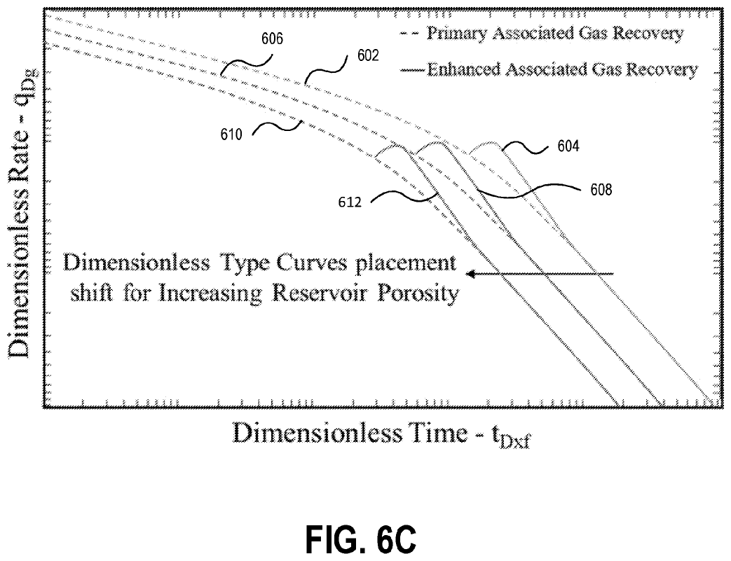

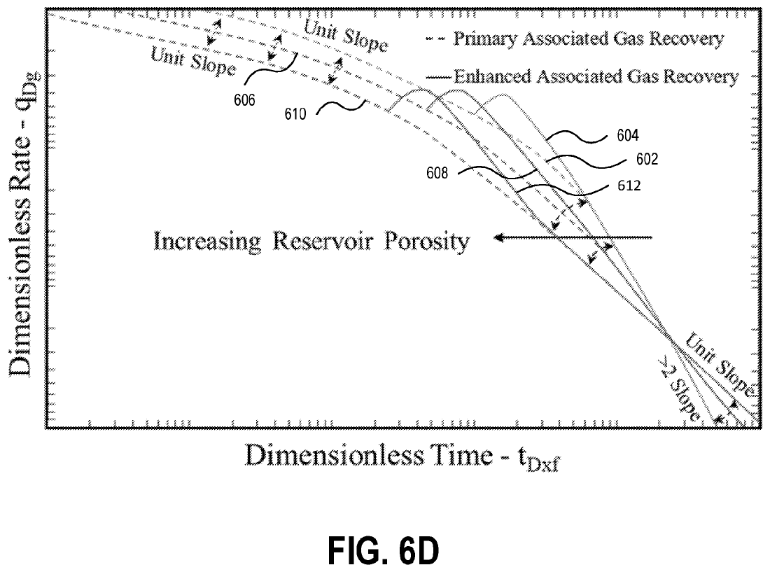

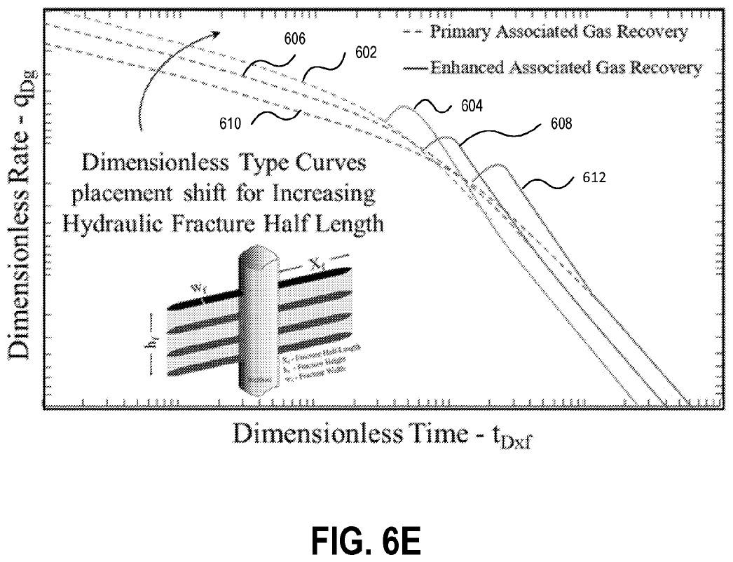

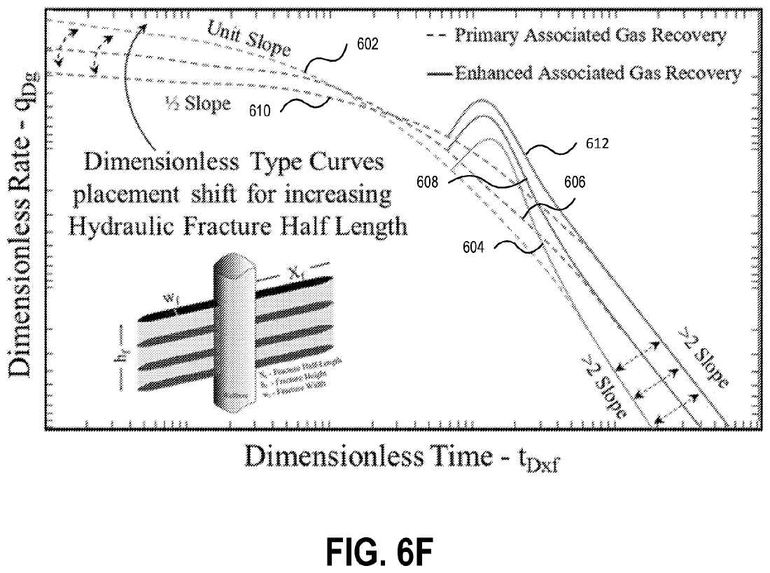

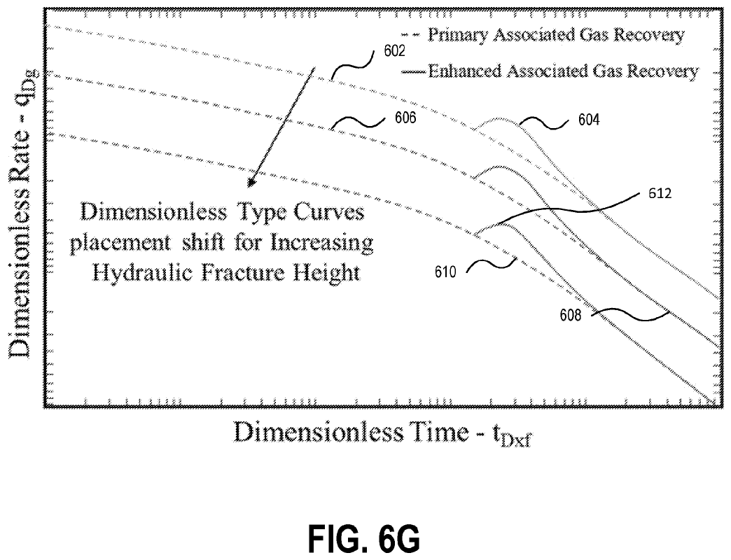

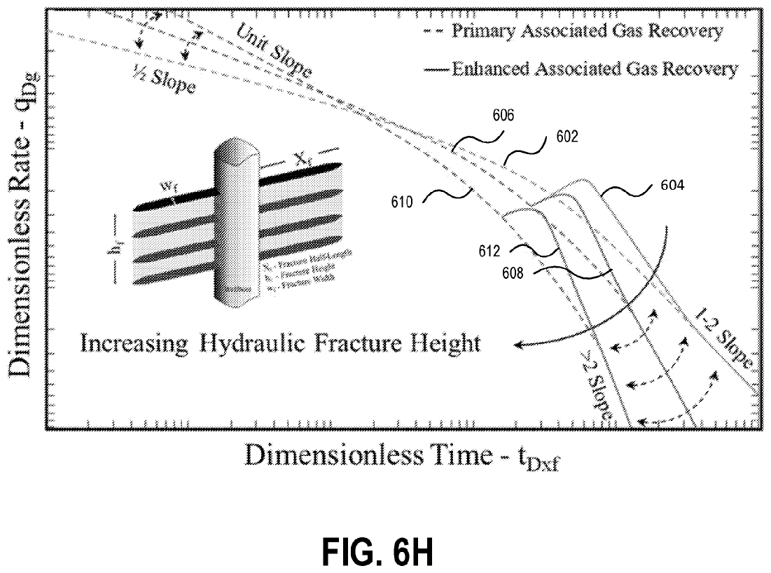

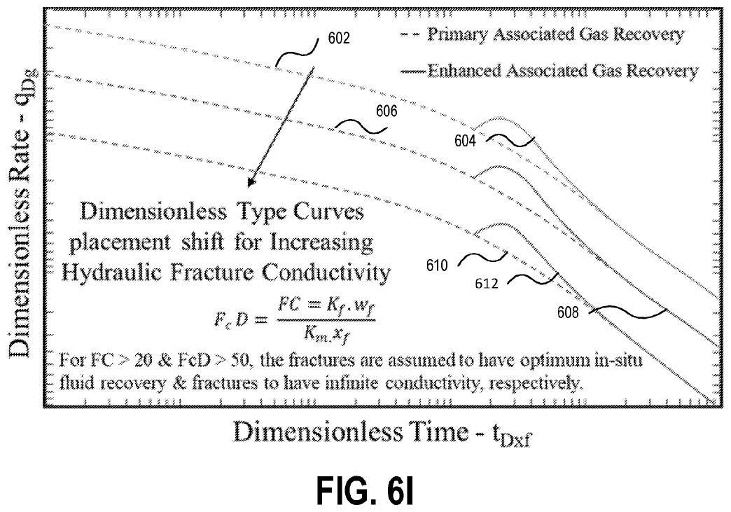

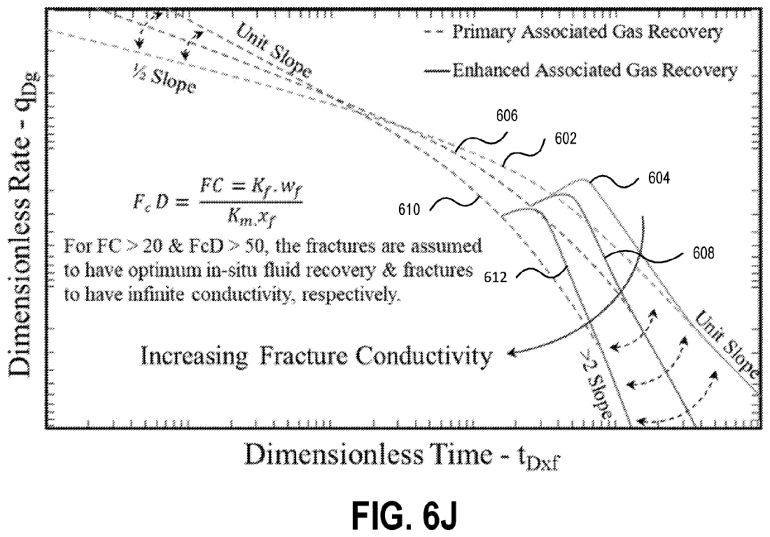

Once training of the model(s) is complete and the compliance of the model(s) with physics laws has been validated (e.g., at block 234 of FIG. 2), the model(s) may be used to generate type curves 240 that may be used for EOR and UEOR, including secondary production, tertiary production, and so on. Moreover, since the model(s) is trained using a data set that covers the range of target reservoir/well properties and is physics-compliant, the model(s) may be used to predict the responses of a variety of different types of reservoirs (e.g., different rock properties, fluid properties, etc.) and wells with improved accuracy. The ability to more accurately predict the response of wells and reservoirs enables generation of type curves that may be utilized for EOR analysis, as compared to existing type curves which are limited to the primary production phase, and may also be used to optimize EOR or UEOR operations according to the W3H factors outlined above. For example, the model(s) may be used to predict the responses of a reservoir to EOR or UEOR operations involving different injection fluids (e.g., CO₂, water, etc.), different volumes of injection fluid, injecting the fluid at different times, injecting the fluid at different locations, injecting the fluid using different techniques, or combinations of these factors. The responses generated by the model(s) enable generation of type curves that may be used to optimize production of hydrocarbons during EOR (e.g., optimize the type of fluid injected into the well, optimize when the fluid(s) should be injected into the well, identify properties of the wells where the fluids should be injected, etc.). To illustrate, at block 250, the type curves generated in accordance with aspects of the present disclosure may be integrated into a tool, such as an application for hydrocarbon production management and/or planning application. An additional advantage that is provided by type curves generated by Aspects of the present disclosure is that they may be generated in a fraction of the time compared to current type curve generation techniques. For example, a system (e.g., the system 100 of FIG. 1) may enable type curves to be generated in as little as 1 hour, as compared to months or years using existing techniques, which are primarily used for primary production and are not suitable for EOR or UEOR due to the lack of certainty with respect to model compliance and understanding of applicable physics. Exemplary aspects of various type curves generated in accordance with aspects of the present disclosure are described in more detail below with reference to FIGS. 5A-6J.

In an aspect, the type curves generated in accordance with aspects of the present disclosure may be integrated into a tool, such as an application for hydrocarbon production management and/or planning application. As briefly described above, the tool may provide functionality for enabling use of the type curves to plan for and manage wells in a reservoir in a manner that optimizes hydrocarbon production. For example and referring back to FIG. 1, a computing device 130 is shown and includes one or more processors 132, a memory 134, and one or more applications 136. It is noted that although not shown in FIG. 1, one or more sensors may be disposed at the reservoir 150 to capture field data (e.g., the field data 222 of FIG. 2), which may be provided to the computing device 130 and/or the EOR computing device 110 via one or more networks 140. In an aspect, the field data may be provided to the computing device 130 and the computing device 130 may provide the field data to the EOR computing device 110.

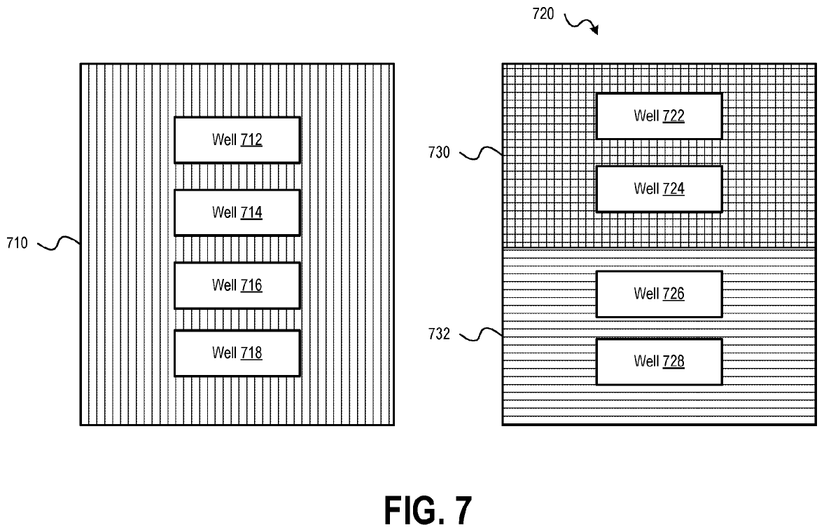

One of the applications 136 may be a tool that incorporates or integrates type curves generated by the EOR computing device 110 and may be used to optimize EOR and/or UEOR operations with respect to a reservoir 150, which may include one or more well sites 152 having drilling equipment 154. As an illustrative example and referring to FIG. 7, a block diagram illustrating aspects of optimization of hydrocarbon production using type curves in accordance with aspects of the present disclosure is shown. In FIG. 7, a reservoir 710 having wells 712-718 drilled thereon and a reservoir 720 having wells 722-728 drilled thereon are shown. The reservoir 710 may be homogeneous with respect to its properties while the reservoir 720 may be non-homogeneous with respect to its properties, such as to include a portion 730 having a set of properties (e.g., rock type, porosity, oil type, etc.) and a portion 732 having a set of properties that include one or more properties that are different from the set of properties associated with the portion 730.

Using type curves generated in accordance with the present disclosure may enable an operator (e.g., a producer of hydrocarbons operating the wells 712-718 and/or the wells 722-728) to identify candidate wells in the reservoirs 710 and 720 for EOR or UEOR. More specifically, the type curves may identify properties of a well suitable for EOR or UEOR for different W3H factors. For example, the type curves generated by Aspects of the present disclosure may classify wells according to various well and reservoir properties such that a particular type curve represents a certain type of well/reservoir properties while another type curve represents a different type of well/reservoir properties. Using the type curves, the operator may identify one or more of the wells 712-718 as candidate wells for EOR and/or UEOR operations. To illustrate, the type curves may indicate that the wells 712, 718 are optimal candidates for EOR or UEOR in the reservoir 710, the well 724 is the optimal candidate for EOR or UEOR in the portion 730 of the reservoir 720, and the well 726 is the optimal candidate for EOR or UEOR in the portion 732 of the reservoir 720. These wells may be identified as optimal candidates based on the rock properties where the wells are located, the type of fluid to be injected, the method for injecting the fluid, the composition of the hydrocarbons the well is producing, or other ones of the W3H factors, which may be indicated by or associated with each of the type curves, as described in more detail below.

Referring back to FIG. 1, using the functionality provided by the EOR computing device 110, as described above with reference to FIGS. 1-4B and 7, a collection of numerical simulation-based EOR responses covering a target range of parameter values is generated that models a reservoir, such as a light oil reservoir through a multiple-fractured horizontal well. These responses may then be used to generate (e.g., via the model 122) type curves that may be subjected to Rate Transient Analysis (RTA) to validate the candidate wells prior to performing EOR or UEOR operations. For example, once candidate wells for EOR or UEOR are identified based on the type curves, well properties, and reservoir properties, field data from the candidate wells may be compared to the type curve to validate candidate wells are targets for EOR UEOR according to the type curve data. If the field data correlates to the type curve, the candidate wells may be selected as wells for EOR or UEOR operations, which may proceed according to the W3H factors indicated by the type curve, which may indicate the injection solvent type and volume, the optimum start of injection and soaking time as well as the frequency of this cyclic process and estimation and the soaking duration for the optimum recovery, as described in more detail below.

Using the above-described techniques enables wells to be identified for EOR and UEOR operations more quickly (e.g., hours or days instead of months or years) and with improved accuracy (e.g., due to the validation of physics compliance of the model(s)). Such capabilities may result in optimized EOR and UEOR operations being carried out more efficiently and result in lower carbon emissions from production of hydrocarbons (e.g., because EOR and UEOR can be performed in an optimal and physics-informed manner). Exemplary SPIC TCs for CO₂ (e.g., injected fluid) and/or hydrocarbon gas EOR that may be generated using the system 100 are described in more detail below with reference to FIGS. 5A-6J. It should be noted that the exemplary type curves described herein are provided for purposes of illustration, rather than by way of limitation and that the system 100 may be used to generate type curves for EOR and UEOR other than those explicitly disclosed and described herein.

Referring to FIGS. 5A and 5B, diagrams showing type curves for oil recovery for reservoirs exhibiting downward shift for heavier to lighter reservoir fluid type and RTA of reservoirs exhibiting crossover shifts for lighter to heavier reservoir fluid types are shown. The type curves shown in FIGS. 5A and 5B include dashed lined 530 representing a primary production phase and solid lines 540 representing a predicted recovery for an EOR or UEOR phase. In particular, FIG. 5A shows three dashed lines 502, 506, 510 corresponding to three different wells or well types and three solid lines ′, 508, 512 corresponding to predicted oil recovery from a reservoir exhibiting a heaver to lighter displacement shift fluid type. It is noted that the solid line 504 corresponds to the predicted oil recovery for a well or well type corresponding to the dashed line 502, the solid line 508 corresponds to the predicted oil recovery for a well or well type corresponding to the dashed line 506, and the solid line 512 corresponds to the predicted oil recovery for a well or well type corresponding to the dashed line 510.

As shown in FIG. 5B, the slopes range from half to unit slope for the primary recovery while the EOR slopes vary between half slope to as high as 2 slope for different types of reservoir fluid types. Using the type curves shown in FIGS. 5A and 5B, an operator may determine when to inject the fluid, how to inject the fluid, the volume of fluid to inject, or other configuration parameters for performing EOR or UEOR operations in an optimum manner. For example, suppose that a well (e.g., the well 712 of FIG. 7) was determined (e.g., using the type curves of FIG. 5A and RTA) to correspond to the dashed line 502. The circle 504′, which highlights the point where the solid line 504 begins, indicates the point in time when EOR or UEOR should begin according to the W3H factors associated with the type curve. As an example, suppose the type curves of FIG. 5A were associated CO₂ as the injected fluid in a particular quantity. Wells matching one of the various type curves of FIG. 5A (e.g., where to inject) may begin EOR or UEOR operations by monitoring primary production (e.g., the dashed lines 502, 506, 510) to determine when the point at which the primary product matches the point where EOR or UEOR is to begin (e.g., the point where corresponding solid lines 504, 508, 512 begin) and at that time (e.g., the when) the operator may inject the specified type of fluid (e.g., what to inject) in the indicated quantity (e.g., how much to inject) using the indicated method (e.g., how to inject), thereby resulting in optimal production of hydrocarbons from one or more wells.

It is noted that the diagram of FIG. 5B shows type curves for a reservoir exhibiting crossover shifts from left to right for lighter to heavier reservoir fluid types is shown. In particular, it can be seen that as compared to FIG. 5A, the dashed lines representing primary production crossover at inflection point 534, as can be seen by dashed line 502 being on top to the left of inflection point 534 and being on bottom to the right of inflection point 534, as indicated by dashed line 502′. As can be seen in FIG. 5B, the specifics regarding the shape, slope, and the placement of the curves can provide useful information about the reservoir behavior. For example, the arrows are different in the first half (e.g., primary recovery) of the figure showing the slope of the curves as the function of reservoir fluid type (i.e., the lighter the fluid, the steeper will be the curves and heavier the fluid, the leaner will be the curve. Similarly, in the second half of the curves (e.g., EOR), the slopes change as the function of reservoir fluid type but in the opposite way as compared to the primary recovery. Regarding the crossover shift, the placement of the crossover on x-axis shifts horizontally depending on the reservoir fluid type. The crossover delays in time with the heavier reservoir fluid type. It is noted that in the description of FIGS. 5C-6J below primary production is indicated with dashed lines and EOR production predictions are indicated using solid lines using the same numbering scheme as above in FIG. 5A.

Referring to FIGS. 5C and 5D, diagrams showing type curves and RTA for reservoirs exhibiting placement shift for increasing reservoir porosity is shown. As can be seen in FIG. 5D, the slope remains unchanged for the primary recovery (i.e. unit slope), while the EOR slopes vary between unit slope (i.e. for higher matrix porosity) to as high as greater than 2 slope for the smaller porosity values. It is noted that in the EOR section of the RTA curves of FIG. 5D, the crossover might be observed if the variation in porosity is significant. For example, the crossover shifts towards the right on x-axis for higher porosity.

Referring to FIGS. 5E and 5F, diagrams showing type curves for reservoirs exhibiting placement shift for increasing hydraulic fracture half-length and RTA analysis of crossover shifts for increasing fracture half-length are shown. As shown in FIG. 5F, the slopes remain unchanged for the primary recovery (i.e. half slope), while the EOR slopes vary between unit slope (i.e. for smaller half-length), to as high as greater than 2 slopes for the larger half-length values. Also, the type curve shape becomes leaner for increasing fracture half-length. As also seen in FIG. 5F, the EOR RTA crossover shifts towards right on x-axis with an increase in fracture half-length.

Referring to FIGS. 5G and 5H, diagrams showing type curves for reservoirs exhibiting placement shift for increasing hydraulic fracture height and RTA analysis of increasing hydraulic fracture height are shown. As can be seen in FIG. 5H, the slopes range from half to unit slope for the primary recovery, while the EOR slopes vary between unit slope to as high as over 2 slope for increasing hydraulic fracture height. As also seen shown, the crossover shifts towards the left on x-axis with an increase in fracture height during primary recovery.

Referring to FIGS. 5I and 5J, diagrams showing type curves for reservoirs exhibiting placement shift for increasing hydraulic fracture conductivity and RTA analysis of increasing hydraulic fracture conductivity are shown. As shown in FIG. 5J, the slopes range from half to unit slope for the primary recovery, while the EOR slopes vary from unit slope to as high as over 2 slope for increasing hydraulic fracture conductivity. As also shown, the crossover shifts towards left on x-axis with an increase in fracture conductivity during primary recovery.

In the description of FIGS. 6A-6J below, dashed lines 602, 606, 610 represent primary recovery and solid lines 604, 608, 612 represent EOR or UEOR recovery. Referring to FIGS. 6A and 6B, diagrams illustrating type curves for reservoirs exhibiting placement shift for lighter to heavier reservoir fluid types and RTA analysis for crossover shifts for lighter to heavier reservoir fluid types are shown. In the diagram of FIG. 6A, the response is shown with a counter-clockwise shift for lighter to heavier reservoir fluid type is shown. As can be seen in FIG. 6B, the slopes for the primary recovery range from unit to half slope while the EOR slopes vary between half slope to as high as 2 slope for different types of reservoir fluid types. As also shown, the crossover shifts from left to right for lighter to heavier reservoir fluid type.

Referring to FIGS. 6C and 6D, diagrams illustrating type curves for reservoirs exhibiting placement shift for increasing reservoir porosity and RTA for increasing reservoir porosity are shown. As shown in FIG. 6D, the slope remains unchanged for the primary recovery (i.e. unit slope), while the EOR slopes vary between unit slope (i.e. for higher matrix porosity), to as high as greater than 2 slope for the smaller porosity values.

Referring to FIGS. 6E and 6F, diagrams illustrating type curves for reservoirs exhibiting placement shift for increasing hydraulic fracture half-length and RTA for increasing hydraulic fracture half-length are shown. As seen in FIG. 6F, the slopes range from unit to half slope for the primary recovery, while the EOR slope for the associated gas recovery is found to be greater than 2 slope for a variety of hydraulic fracture half-lengths.

Referring to FIGS. 6G and 6H, diagrams illustrating type curves for reservoirs exhibiting placement shift for increasing hydraulic fracture height and RTA for increasing hydraulic fracture height are shown. As shown in FIG. 6H, the slopes range from half to unit slope for the primary recovery, while the EOR slopes vary from unit slope to as high as over 2 slope for increasing hydraulic fracture height.

Referring to FIGS. 6I and 6J, diagrams illustrating type curves for reservoirs exhibiting placement shift for increasing hydraulic fracture conductivity and RTA for increasing hydraulic fracture conductivity are shown. As shown in FIG. 6J, the slopes range from half to unit slope for the primary recovery while the EOR slopes vary from unit slope to as high as over 2 slope for increasing hydraulic fracture conductivity.

It should be understood that the exemplary type curves of FIGS. 5A-6J have been provided for purposes of illustration, rather than by way of limitation and that Aspects of the present disclosure may generate type curves for EOR and UEOR having more than three type curves or less than three type curves if desired. Furthermore, it is noted that while FIGS. 5A-6J pertain to type curves based on a single property of a reservoir or well, it is to be understood that type curves may be generated based on multiple reservoir and/or well properties in combination if desired (e.g., reservoir porosity and fluid composition; fracture height, crossover, and fluid type; etc.).

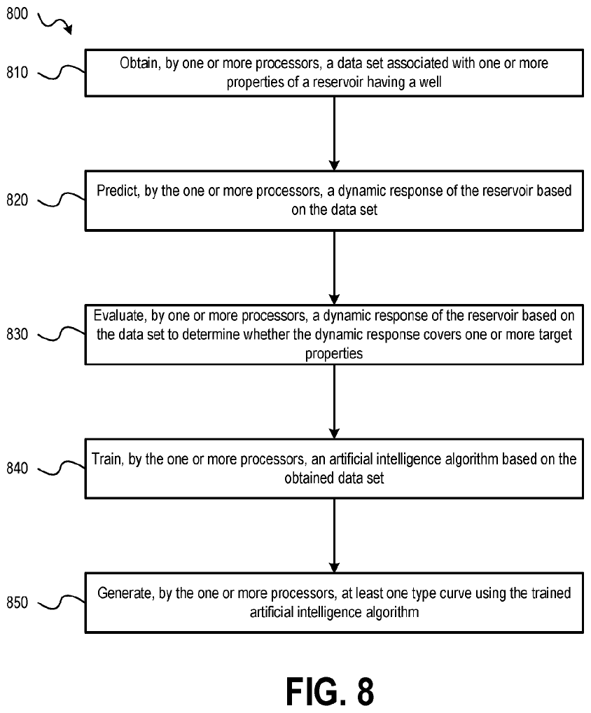

Referring to FIG. 8, a flow diagram of an exemplary method for generating EOR type curves in accordance with aspects of the present disclosure is shown as a method 800 At step 810, the method 800 includes obtaining, by one or more processors, a data set associated with one or more properties of a reservoir. As explained above with reference to FIGS. 2 and 4A, 4B, the data set may be obtained from field data (e.g., the field data 202 of FIG. 2) and simulation data (e.g., the simulation data 224 of FIG. 2). At step 820, the method 800 includes predicting, by the one or more processors, a dynamic response of the reservoir based on the data set. The dynamic response is associated with a predicted recovery of hydrocarbons from the reservoir via a well during EOR. As explained above, the dynamic response may be complete (e.g., not include gaps), as in FIG. 4B, or may be incomplete (e.g., include gaps), as in the gaps 404A-404H of FIG. 4A.

At step 830, the method 800 includes evaluating, by the one or more processors, a dynamic response of the reservoir based on the data set to determine whether the dynamic response covers one or more target properties, wherein one or more simulations are executed to generate additional data for the data set in response to a determination that the dynamic response does not cover the one or more target properties.

At step 840, the method 800 includes training, by the one or more processors, an artificial intelligence algorithm based on the obtained data set. As explained above with reference to FIGS. 1 and 2, the artificial intelligence algorithm may be trained to generate one or more type curves, such as the type curves shown in FIGS. 5A-6J. In an aspect, the training may be configured to account for an impact of physics on the reservoir during EOR. For example, the training may involve defining one or more PCI hyperparameters associated with physics defined behaviors (PDBs) representing or indicating expected responses/behavior changes with respect to variation of input parameter values due to the impact of physics. For example, a PCI hyperparameter may be associated with a volume of fluid to be injected and the PDB associated with the fluid volume PCI hyperparameter may indicate how the reservoir is expected to respond to different volumes of fluid being injected into the reservoir (e.g., the response may be minimal for injection of a small volume of fluid into the reservoir and the response may increase as the volume of fluid that is injected into the reservoir increases). During training of the artificial intelligence algorithm, a PCI score may be generated to indicate whether the artificial intelligence algorithm is learning the PDB and physics behind the PDB associated with each PCI hyperparameter (e.g., individual PCI hyperparameter PCI score and/or aggregate PCI hyperparameter scores representing the artificial intelligence algorithm's ability to learn all PDBs and applicable physical laws applicable to the modeled use case, such as EOR). When training is complete, the artificial intelligence algorithm is enabled to predict responses of the reservoir over a range of parameter values while accommodating and accounting for physical laws that control the response of the reservoir. This may enable the artificial intelligence algorithm to be used to analyze many different types of reservoirs and EOR techniques (e.g., different volumes of fluid, different fluid types, different fluid injection methods, different geological or rock properties of reservoirs, etc.), thereby providing a robust mechanism for evaluating reservoirs and wells for EOR. Moreover, because the artificial intelligence algorithm understands the physical laws that govern the behavior or response of the reservoir, the artificial intelligence algorithm may be used to generate type curves and predictions for tertiary and later EOR stages without requiring any or significant amounts of additional training and data, thereby increasing the utility of the artificial intelligence algorithm.

At step 850, the method 800 includes generating, by the one or more processors, at least one type curve using the trained artificial intelligence algorithm. As explained above with reference to FIGS. 5A-6J, the at least one type curve may indicate one or more properties related to hydrocarbon recovery during EOR. For example, the at least one type curve may provide information associated with the W3H factors (e.g., where to inject, when to inject, what to inject, and how to inject), which may enable identification of candidate wells within an existing reservoir that may be suitable for EOR. To illustrate, each type curve generated by the artificial intelligence algorithm may be associated with a different set of properties (e.g., rock properties, fluid properties, rock and fluid interaction properties, hydraulic fracture design properties, operational constraints, other properties, or a combination thereof). To identify candidate wells, an operator (or an application, such as an application stored as the instructions 118 of FIG. 1 and executable by the one or more processors 112 of FIG. 1) may determine properties associated with one or more locations corresponding to the reservoir, as explained above with reference to FIG. 7, and may compare the properties associated with the one or more locations to the different sets of properties associated with each of the type curves. The candidate wells may be identified based on identification of locations associated with properties corresponding to a set of properties associated with a particular type curve.

The method 800 enables evaluation and identification of candidate wells for EOR in a more quickly and efficiently as compared to the type curve techniques currently used for primary production. Moreover, the method 800 also provides a greater degree of accuracy with respect to the candidate well locations for EOR due to the ability of the artificial intelligence algorithm(s) to account for the impact of physics on the reservoir during EOR, such as to account for the impact on the reservoir of injecting a volume of fluid into a portion of the reservoir having a particular set of properties, which may include reservoir-specific properties (e.g., rock properties, fluid and hydraulic fracture properties, etc.) and well properties (e.g., production constraints, well configuration, etc.), as explained above. Another advantage provided by the method 800 is the ability to generate type curves for EOR, including tertiary production and beyond, without requiring an artificial intelligence algorithm to be completely redesigned from the ground up or significantly modified. For example, the artificial intelligence algorithm and its ability to learn the physics and physics defined behaviors of the reservoir enables the artificial intelligence algorithm to account for different physics impacts for secondary production, tertiary production, and so on. Moreover, the use of simulations to supplement the data set used to train the model may enable additional training data to be generated if needed, thereby overcoming limitations that would be imposed if restricted to field data alone.

As noted above, prior type curve generation systems are primarily used for primary production phases of hydrocarbon recovery and are inadequate for use in EOR scenarios because primary production does not involve the same physics as EOR. Moreover, because those prior type curve generation systems do not properly account for the physics of EOR, any type curves generated by those prior systems for an EOR application are inaccurate and unlikely to provide useful information for optimizing EOR. As shown above, the method 800 represents a new process for optimizing recovery of hydrocarbons from a reservoir during EOR and an improvement to type curve generation systems as tools for planning and executing EOR phases of hydrocarbon recovery.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to various ones of FIGS. 1-8 include processors, electronics devices, hardware devices, electronics components, logical circuits, memories, software codes, firmware codes, among other examples, or any combination thereof. In addition, features discussed herein may be implemented via specialized processor circuitry, via executable instructions, or combinations thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits, and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules, and circuits described in connection with the aspects disclosed herein may be implemented or performed with a general purpose single-or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or any conventional processor, controller, microcontroller, or state machine. In some implementations, a processor may also be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or any combination thereof. Implementations of the subject matter described in this specification also may be implemented as one or more computer programs, that is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media can include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, hard disk, solid state disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, various terminology is for the purpose of describing particular implementations only and is not intended to be limiting of implementations. For example, as used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). The term “coupled” is defined as connected, although not necessarily directly, and not necessarily mechanically; two items that are “coupled” may be unitary with each other. the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified—and includes what is specified; e.g., substantially 90 degrees includes 90 degrees and substantially parallel includes parallel—as understood by a person of ordinary skill in the art. In any disclosed aspect, the term “substantially” may be substituted with “within [a percentage] of” what is specified, where the percentage includes 0.1, 1, 5, and 10 percent; and the term “approximately” may be substituted with “within 10 percent of” what is specified. The phrase “and/or” means and or.

Although the aspects of the present disclosure and their advantages have been described in detail, it should be understood that various changes, substitutions and alterations can be made herein without departing from the spirit of the disclosure as defined by the appended claims. Moreover, the scope of the present application is not intended to be limited to the particular implementations of the process, machine, manufacture, composition of matter, means, methods and processes described in the specification. As one of ordinary skill in the art will readily appreciate from the present disclosure, processes, machines, manufacture, compositions of matter, means, methods, or operations, presently existing or later to be developed that perform substantially the same function or achieve substantially the same result as the corresponding aspects described herein may be utilized according to the present disclosure. Accordingly, the appended claims are intended to include within their scope such processes, machines, manufacture, compositions of matter, means, methods, or operations.

What is claimed is:

1. A method for generating type curves for enhanced oil recovery (EOR), the method comprising:
obtaining, by one or more processors, a data set associated with one or more properties of a reservoir having a well;
predicting, by the one or more processors, a dynamic response of the reservoir based on the data set, wherein the dynamic response indicates properties of a predicted recovery of hydrocarbons from the reservoir;
evaluating, by the one or more processors, a dynamic response of the reservoir to determine whether the dynamic response covers one or more target properties, wherein one or more simulations are executed to generate additional data for the data set in response to a determination that the dynamic response does not cover the one or more target properties;
training, by the one or more processors, an artificial intelligence algorithm based on the obtained data set, wherein the artificial intelligence algorithm is trained to generate one or more type curves for EOR, and wherein the artificial intelligence algorithm is configured to learn physics defined behaviors of the reservoir during EOR based on the training; and
generating, by the one or more processors, at least one type curve using the trained artificial intelligence algorithm, the at least one type curve indicating one or more properties of hydrocarbon recovery during EOR.

2. The method of claim 1, further comprising identifying a location for the EOR based at least in part on a particular type curve of the at least one type curve, wherein the particular type curve is associated with a set of properties, and wherein the location is identified by locating an area within the reservoir having properties corresponding to the set of properties associated with the particular type curve.

3. The method of claim 1, wherein the at least one type curve comprises a plurality of type curves, each type curve of the plurality of type curves associated with a different set of properties.

4. The method of claim 3, wherein the set of properties associated with each type curve comprises properties selected from the list consisting of: rock properties, fluid properties, rock and fluid interaction properties, hydraulic fracture design properties, operational constraints, or a combination thereof.

5. The method of claim 4, wherein the one or more fluid properties comprise properties associated with pressure, volume, and fluid composition; wherein the one or more rock properties comprise properties associated with a type of rock present in the reservoir, a porosity of the rock, or both; wherein the one or more rock and fluid interaction properties comprise properties associated with the hydraulic fracture design properties, including but not limited to, a fracture conductivity, a fracture half-length, a fracture height, a number of hydraulic fracture clusters per stage, or a combination thereof; and wherein the one or more operational constraints comprise one or more equipment constraints, one or more resource constraints, or both.

6. The method of claim 1, wherein each type curve of the at least one type curve indicates a type of fluid to inject into the reservoir during EOR, a volume of the fluid to inject into the reservoir during EOR, properties of a location for injecting the fluid into the reservoir during EOR, a soaking time associated with injecting the fluid into the reservoir during EOR, when to inject the fluid into the reservoir during EOR, or a combination thereof.

7. The method of claim 1, wherein evaluating the dynamic response of the reservoir to determine whether the dynamic response covers the one or more target properties comprising identifying portions of the dynamic response that are incomplete or missing over a target range of response values.

8. The method of claim 1, further comprising:
associating one or more physics defined behaviors with one or more hyperparameters of the artificial intelligence algorithm; and
verifying the artificial intelligence algorithm learns the physics defined behaviors during the training.

9. A system for generating type curves for enhanced oil recovery (EOR), the system comprising:
a memory; and
one or more processors configured to:
predict a dynamic response of a reservoir based on a data set, wherein the dynamic response indicates properties of a predicted recovery of hydrocarbons from the reservoir;
evaluate the dynamic response of the reservoir to determine whether the dynamic response covers one or more target properties;
execute one or more simulations to generate additional data for the data set in response to a determination that the dynamic response does not cover the one or more target properties, and wherein one or more additional dynamic responses are generated and evaluated subsequent to generating the additional data for the data set;
train an artificial intelligence algorithm based on the obtained data set, wherein the artificial intelligence algorithm is trained to generate one or more type curves for EOR, and wherein the artificial intelligence algorithm is configured to learn physics defined behaviors of the reservoir during EOR based on the training; and
generate at least one type curve using the trained artificial intelligence algorithm, the at least one type curve indicating one or more properties of hydrocarbon recovery during EOR.

10. The system of claim 9, wherein the one or more processors are configured to identify a location for the EOR based at least in part on a particular type curve of the at least one type curve, wherein the particular type curve is associated with a set of properties, and wherein the location is identified by locating an area within the reservoir having properties corresponding to the set of properties associated with the particular type curve.

11. The system of claim 9, wherein the at least one type curve comprises a plurality of type curves, each type curve of the plurality of type curves associated with a different set of properties.

12. The method of claim 11, wherein the set of properties associated with each type curve comprises properties selected from the list consisting of: rock properties, fluid properties, rock and fluid interaction properties, hydraulic fracture design properties, operational constraints, or a combination thereof.

13. The system of claim 12, wherein the one or more fluid properties comprise properties associated with pressure, volume, and fluid composition; wherein the one or more rock properties comprise properties associated with a type of rock present in the reservoir, a porosity of the rock, or both; wherein the one or more rock and fluid interaction properties comprise properties associated with a fracture conductivity, a fracture half-length, a fracture height, a number of hydraulic fracture clusters per stage, or a combination thereof; and wherein the one or more operational constraints comprise one or more equipment constraints, one or more resource constraints, or both.

14. The system of claim 9, wherein each type curve of the at least one type curve indicates a type of fluid to inject into the reservoir during EOR, a volume of the fluid to inject into the reservoir during EOR, properties of a location for injecting the fluid into the reservoir during EOR, a soaking time associated with injecting the fluid into the reservoir during EOR, when to inject the fluid into the reservoir during EOR, or a combination thereof.

15. The system of claim 9, wherein evaluating the dynamic response of the reservoir to determine whether the dynamic response covers the one or more target properties comprises identifying portions of the dynamic response that are incomplete or missing over a target range of response values.

16. The system of claim 9, wherein the one or more processors are configured to:
associate one or more physics defined behaviors with one or more hyperparameters of the artificial intelligence algorithm; and
verify the artificial intelligence algorithm learns the physics defined behaviors during the training.

17. A non-transitory computer-readable storage medium storing instructions that, when executed by one or more processors, cause the one or more processors to perform operations for generating type curves for enhanced oil recovery, the operations comprising:
obtaining, by one or more processors, a data set associated with one or more properties of a reservoir having a well;
predicting, by the one or more processors, a dynamic response of the reservoir based on the data set, wherein the dynamic response indicates properties of a predicted recovery of hydrocarbons from the reservoir;
evaluating, by the one or more processors, a dynamic response of the reservoir to determine whether the dynamic response covers one or more target properties, wherein one or more simulations are executed to generate additional data for the data set in response to a determination that the dynamic response does not cover the one or more target properties;
training, by the one or more processors, an artificial intelligence algorithm based on the obtained data set, wherein the artificial intelligence algorithm is trained to generate one or more type curves for EOR and to learn physics defined behaviors of the reservoir during EOR based on the training; and
generating, by the one or more processors, at least one type curve using the trained artificial intelligence algorithm, the at least one type curve indicating one or more properties of hydrocarbon recovery during EOR.

18. The non-transitory computer-readable storage medium of claim 17, wherein the at least one type curve comprises a plurality of type curves, each type curve of the plurality of type curves associated with a different set of properties, wherein the set of properties associated with each type curve comprises properties selected from the list consisting of: rock properties, fluid properties, rock and fluid interaction properties, hydraulic fracture design properties, operational constraints, or a combination thereof, the operations further comprising:
determining properties associated with one or more locations corresponding to the reservoir; and
comparing properties associated with the one or more locations and the different sets of properties associated with the plurality of type curves; and
identifying a location for performing the EOR based at least in part on the comparing, wherein the location is associated with properties corresponding to a set of properties associated with a particular type curve of the plurality of type curves.

19. The non-transitory computer-readable storage medium of claim 17, wherein evaluating the dynamic response of the reservoir to determine whether the dynamic response covers the one or more target properties comprises identifying portions of the dynamic response that are incomplete or missing over a target range of response values.

20. The non-transitory computer-readable storage medium of claim 17, the operations further comprising:
associating one or more physics defined behaviors with one or more hyperparameters of the artificial intelligence algorithm; and
verifying the artificial intelligence algorithm learns the physics defined behaviors during the training.
